(19) United States
(12) Patent Application Publication
(10) Pub. No.: US 2025/0105159 A1
(43) Pub. Date: Mar. 27, 2025

(54) FAN-OUT LEVEL SEMICONDUCTOR PACKAGE

(71) Applicant: SAMSUNG ELECTRONICS CO., LTD., SUWON-SI (KR)

(72) Inventors: Pyunghwa Han, Suwon-si (KR); Dahee Kim, Suwon-si (KR); Bongsoo Kim, Suwon-si (KR); Chobi Kim, Suwon-si (KR)

(21) Appl. No.: 18/823,171

(22) Filed: Sep. 3, 2024

(30) Foreign Application Priority Data
Sep. 26, 2023 (KR) 10-2023-0129562

(51) Int. Cl. H01L 23/538; H01L 23/00; H01L 23/16; H01L 23/31; H01L 23/498; H01L 25/10

(52) U.S. Cl. CPC H01L 23/5385; H01L 23/16; H01L 23/5386; H01L 23/3107; H01L 23/49816; H01L 24/08; H01L 25/105; H01L 2224/08225; H01L 2225/1041

(57) ABSTRACT

A semiconductor package includes a first wiring structure, an extension structure disposed on the first wiring structure, including an extension base layer and a plurality of via structures, and having a mounting space passing through the extension base layer. The plurality of via structures include a plurality of via connection patterns, a semiconductor chip disposed in the mounting space and electrically connected to the first wiring structure, a filling insulating layer filling the mounting space, and a second wiring structure disposed on the extension structure and the filling insulating layer and electrically connected to the first wiring structure. Lowermost via connection patterns, among the plurality of via connection patterns, include a plurality of first lower connection pads, and the extension base layer includes base dams respectively passing through the plurality of first lower connection pads.

### CROSS-REFERENCE TO RELATED APPLICATION

This application claims priority under 35 U.S.C. § 119 to Korean Patent Application No. 10-2023-0129562, filed on Sep. 26, 2023, in the Korean Intellectual Property Office, the disclosure of which is incorporated by reference herein in its entirety.

### TECHNICAL FIELD

The inventive concept relates to a semiconductor package, and more particularly, to a fan-out panel level package (FOPLP) and a package-on-package (POP) including the FOPLP.

### DISCUSSION OF THE RELATED ART

In accordance with the rapid development of the electronics industry and the demand of users, electronic devices are becoming more compact, multi-functional, and larger in capacity, and thus, highly integrated semiconductor chips are being developed.

Therefore, for highly integrated semiconductor chips having an increased number of input/output (I/O) connection terminals, semiconductor packages having connection terminals that ensure connection reliability have been designed. For example, to prevent interference between connection terminals, fan-out semiconductor packages, such as fan-out panel level packages (FOPLPs), have been developed to increase distances between the connection terminals.

### SUMMARY

A semiconductor package includes a first wiring structure. An extension structure is disposed on the first wiring structure, the extension structure including an extension base layer and a plurality of via structures, and having a mounting space passing through the extension base layer, wherein the plurality of via structures includes a plurality of via connection patterns disposed on upper and lower surfaces of the extension base layer and a plurality of extension vias connecting two via connection patterns, among the plurality of via connection patterns, to each other, the two via connection patterns being at different vertical levels from one another. A semiconductor chip is disposed in the mounting space and is electrically connected to the first wiring structure. A filling insulating layer fills the mounting space. A second wiring structure is disposed on the extension structure and the filling insulating layer and is electrically connected to the first wiring structure through the plurality of via structures. The lowermost via connection patterns, among the plurality of via connection patterns, includes a plurality of first lower connection pads. The extension base layer includes base dams respectively passing through the plurality of first lower connection pads and protruding and extending from the plurality of first lower connection pads.

A semiconductor package includes a first wiring structure. A second wiring structure is disposed above the first wiring structure. An extension structure is disposed between the first wiring structure and the second wiring structure and has a mounting space passing through the extension structure from an upper surface to a lower surface thereof. A semiconductor chip is disposed inside the mounting space. A filling insulating layer fills the mounting space and covers the upper surface of the semiconductor chip and an upper surface of the extension structure. The extension structure includes a plurality of extension base layers stacked on each other, a plurality of via connection patterns disposed on the upper and lower surfaces of each of the plurality of extension base layers, and a plurality of extension vias passing through at least one extension base layer, among the plurality of extension base layers, and connecting two via connection patterns, among the plurality of via connection patterns, to each other which are at different vertical levels from one another. Lowermost via connection patterns, among the plurality of via connection patterns, include a plurality of first lower connection pads arranged around the mounting space and each having a pad trench, and a plurality of second lower connection pads at least partially surrounding the plurality of first lower connection pads. The extension base layer includes a base dam which passes through each of the plurality of first lower connection pads while filling the pad trench, and protrudes downward from a lower surface of each of the plurality of first lower connection pads.

A semiconductor package includes a first wiring structure including a first redistribution insulating layer, a plurality of first redistribution line patterns disposed on at least one of upper and lower surfaces of the first redistribution insulating layer, and a plurality of first redistribution vias passing through the first redistribution insulating layer and respectively connected to some of the plurality of first redistribution line patterns. An extension structure is disposed on the first wiring structure, the extension structure including a plurality of extension base layers and a plurality of via structures passing through the plurality of extension base layers and connected to some of the plurality of first redistribution vias, and having a mounting space passing through the plurality of extension base layers. A semiconductor chip is disposed in the mounting space and includes a plurality of chip pads connected to the others of the plurality of first redistribution vias. A filling insulating layer fills the mounting space and covers an upper surface of the semiconductor chip and an upper surface of the extension structure. A second wiring structure is disposed on the filling insulating layer and includes a second redistribution insulating layer, a plurality of second redistribution line patterns disposed on at least one of the upper and lower surfaces of the second redistribution insulating layer, and a plurality of second redistribution vias passing through the second redistribution insulating layer and respectively connected to some of the plurality of second redistribution line patterns. The second wiring structure is electrically connected to the first wiring structure through the plurality of via structures. The plurality of via structures includes a plurality of via connection patterns disposed on upper and lower surfaces of each of the plurality of extension base layers and a plurality of extension vias passing through at least one extension base layer and connecting two via connection patterns, among the plurality of via connection patterns, to each other, the two via connection patterns being at different vertical levels from one another. Lowermost via connection patterns, among the plurality of via connection patterns, are buried in a lowermost extension base layer, among the plurality of extension base layers, and include a plurality of first lower connection pads arranged around the mounting space and each having a pad trench and a plurality of second lower connection pads at least partially surrounding the plurality of first lower connection pads. The extension base layer includes a base dam which passes through each of the plurality of first lower connection pads while filling the pad trench and extends into the first redistribution insulating layer.

### BRIEF DESCRIPTION OF THE DRAWINGS

Embodiments will be more clearly understood from the following detailed description taken in conjunction with the accompanying drawings in which:

FIG. 1A is a cross-sectional view of a semiconductor package, which is a fan-out panel level package (FOPLP), according to embodiments;

FIG. 1B is an enlarged cross-sectional view showing IB region of FIG. 1A;

FIG. 1C is an enlarged cross-sectional view showing IC region of FIG. 1A;

FIG. 1D is an enlarged cross-sectional view showing ID region of FIG. 1C;

FIGS. 2A to 2J are enlarged plan views showing a lower extension connection pad and a surrounding region thereof in a semiconductor package, which is an FOPLP, according to embodiments;

FIG. 3A is a plan view of a semiconductor package, which is an FOPLP, according to embodiments;

FIG. 3B is an enlarged plan view showing a second lower connection pad and a surrounding region thereof;

FIG. 3C is an enlarged plan view showing a first lower connection pad and a surrounding region thereof;

FIG. 4A is a plan view of a semiconductor package, which is an FOPLP, according to embodiments;

FIG. 4B is an enlarged plan view showing a second lower connection pad and a surrounding region thereof;

FIG. 4C is an enlarged plan view showing a first lower connection pad and a surrounding region thereof;

FIGS. 5A to 5L are cross-sectional views describing a method of manufacturing a semiconductor package, which is an FOPLP, according to embodiments; and

FIG. 6 is a cross-sectional view of a semiconductor package, which is a package-on-package, according to embodiments.

### DETAILED DESCRIPTION OF THE EMBODIMENTS

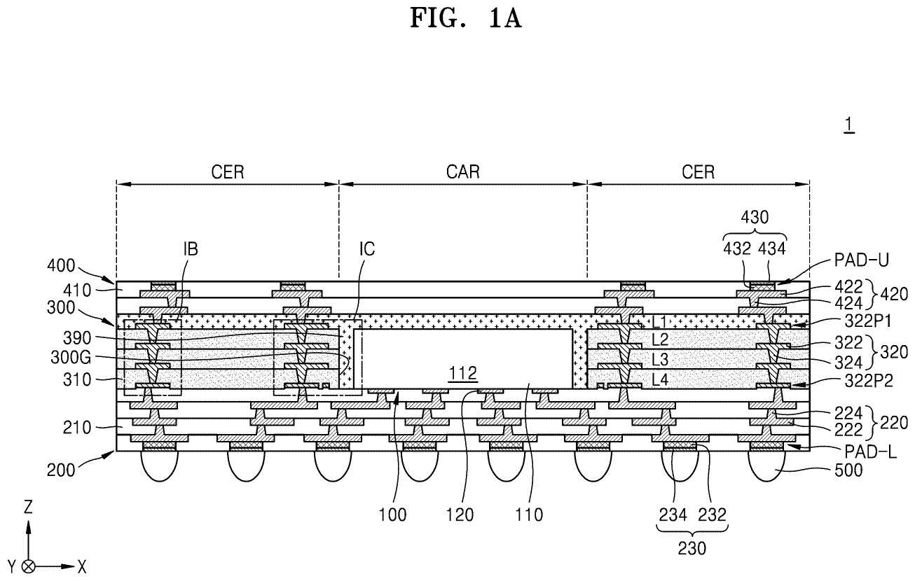

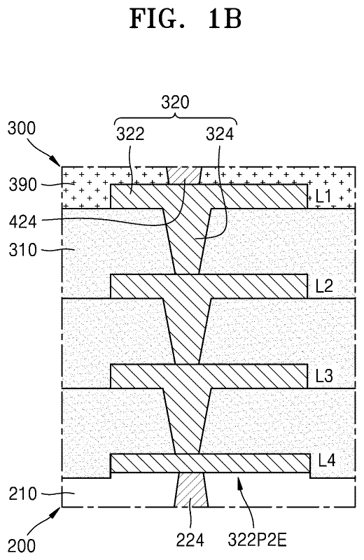

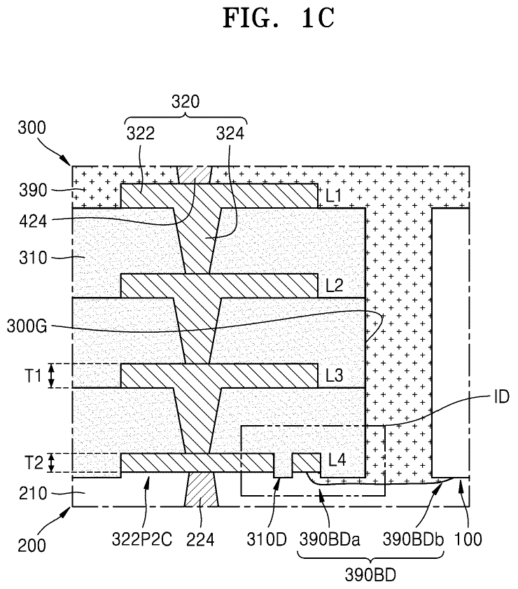

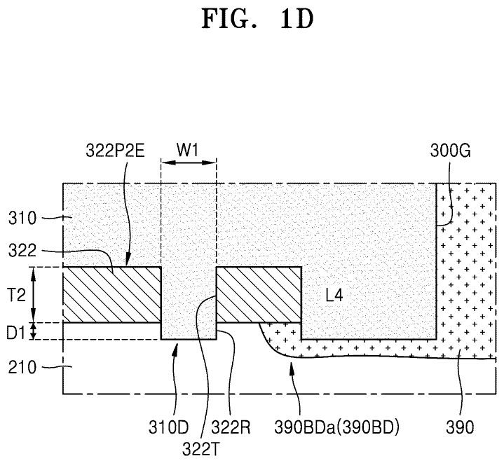

FIGS. 1A to 1D are cross-sectional views of a semiconductor package 1, which is a fan-out panel level package (FOPLP), according to embodiments.

Referring to FIGS. 1A to 1D together, the semiconductor package 1 may include a first wiring structure 200, a second wiring structure 400 disposed above the first wiring structure 200, at least one semiconductor chip 100 disposed between the first wiring structure 200 and the second wiring structure 400, and an expanded layer 300 (or referred to as an extension structure) disposed between the first wiring structure 200 and the second wiring structure 400 and at least partially surrounding the at least one semiconductor chip 100. The extension structure 300 may electrically connect the first wiring structure 200 and the second wiring structure 400 to each other. In some embodiments, the semiconductor package 1 may include a fan out type panel level package (FOPLP). The semiconductor package 1 may have a chip accommodation region CAR in which at least one semiconductor chip 100 is located and a chip peripheral region CER around the chip accommodation region CAR. The chip accommodation region CAR may have a rectangular shape in a plan view and the chip peripheral region CER may at least partially surround the chip accommodation region CAR in the plan view.

In some embodiments, at least one of the first wiring structure 200 and the second wiring structure 400 may be formed by a redistribution process. The first wiring structure 200 and the second wiring structure 400 may be referred to as a first redistribution structure and a second redistribution structure, respectively, or may be referred to as a lower redistribution structure and an upper redistribution structure, respectively. In some embodiments, the semiconductor package 1 may be formed by a chip-first method in which the extension structure 300 and at least one semiconductor chip 100 are formed, and then, the first wiring structure 200 and the second wiring structure 400 are formed. In some embodiments, at least one of the first wiring structure 200 and the second wiring structure 400 may include a printed circuit board. The first wiring structure 200 may include a first redistribution insulating layer 210 and a plurality of first redistribution patterns 220. The first redistribution insulating layer 210 may at least partially surround the plurality of first redistribution patterns 220. In some embodiments, the first wiring structure 200 may include a plurality of first redistribution insulating layers 210 stacked on each other. The first redistribution insulating layer 210 may include an organic material. For example, the first redistribution insulating layer 210 may include a photo imageable dielectric or a photosensitive polyimide or include a build-up film, such as an Ajinomoto build-up film (ABF).

The plurality of first redistribution patterns 220 may include a plurality of first redistribution line patterns 222 and a plurality of first redistribution vias 224. In some embodiments, the plurality of first redistribution patterns 220 may further include a plurality of first redistribution seed layers. The plurality of first redistribution patterns 220 may include, for example, metals, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy of the metals, but the embodiment is not necessarily limited thereto. In some embodiments, the first redistribution line patterns 222 and the first redistribution vias 224 may include the same material. The first redistribution seed layer may include a material different from those of the first redistribution line patterns 222 and the first redistribution vias 224. In some embodiments, each of the first redistribution line patterns 222 and the first redistribution vias 224 may include copper. For example, the first redistribution line pattern 222 and the first redistribution via 224 may include copper or an alloy of copper. In some embodiments, the first redistribution seed layer may include titanium. For example, the first redistribution seed layer may include titanium or titanium nitride.

The plurality of first redistribution vias 224 may pass through the at least one first redistribution insulating layer 210 and may then contact and be connected to some of the plurality of first redistribution line patterns 222. In some embodiments, the plurality of first redistribution vias 224 may each have a tapered shape extending from the bottom to the top with a decreasing horizontal width. For example, the horizontal width of the plurality of first redistribution vias 224 may increase in the direction away from the at least one semiconductor chip 100.

In some embodiments, at least some of the plurality of first redistribution line patterns 222 may be formed together with some of the plurality of first redistribution vias 224 to form integrated bodies. For example, the first redistribution line pattern 222 and the first redistribution via 224 in contact with the upper surface of the first redistribution line pattern 222, for example, the first redistribution via 224 extending from the upper surface of the first redistribution line pattern 222, may be formed together to form an integrated body. For example, the horizontal width of each of the plurality of first redistribution vias 224 may decrease in a direction away from the first redistribution line pattern 222 integrated therewith. The first redistribution seed layer may cover upper portions of the first redistribution line pattern 222 and the first redistribution via 224, which are integrated with each other. For example, the first redistribution seed layer may cover the upper surface of the first redistribution line pattern 222 and the side and upper surfaces of the first redistribution via 224, among surfaces of the first redistribution line pattern 222 and the first redistribution via 224 that are integrated with each other. The first redistribution seed layer might not cover the side and lower surfaces of the first redistribution line pattern 222.

The first wiring structure 200 may include a plurality of lower connection pads PAD-L disposed on the lower surface of the first wiring structure 200. In some embodiments, each of the plurality of lower connection pads PAD-L may include a portion of the first redistribution line pattern 222 and a lower connection pad layer 230 that covers the lower surface of the portion of the first redistribution line pattern 222. The lower connection pad layer 230 may include a first lower metal layer 232 and a second lower metal layer 234, which are sequentially stacked on the lower surface of the portion of the first redistribution line pattern 222. In some embodiments, the first lower metal layer 232 may include nickel (Ni) and the second lower metal layer 234 may include gold (Au), but the embodiment is not necessarily limited thereto. A plurality of external connection terminals 500 may be respectively attached to the plurality of lower connection pads PAD-L. The plurality of external connection terminals 500 may connect the semiconductor package 1 to exterior circuitry, such as a printed circuit board (PCB).

At least one semiconductor chip 100 may be attached to the first wiring structure 200. The semiconductor chip 100 may include a semiconductor substrate 110 having an active surface and an inactive surface opposite to each other, a semiconductor device 112 formed on the active surface of the semiconductor substrate 110, and a plurality of chip pads 120 disposed on the semiconductor device 112. The semiconductor chip 100 may have a first surface and a second surface that are opposite to each other. The plurality of chip pads 120 may be disposed on the first surface of the semiconductor chip 100. The second surface of the semiconductor chip 100 may include the inactive surface of the semiconductor substrate 110. The active surface of the semiconductor substrate 110 is close to the first surface of the semiconductor chip 100, and thus, the active surface of the semiconductor substrate 110 and the first surface of the semiconductor chip 100 are shown without distinction. In some embodiments, the plurality of chip pads 120 may protrude from the first surface of the semiconductor chip 100 and be buried in the first wiring structure 200. For example, at least a portion of each of the plurality of chip pads 120 may be buried in the uppermost one of the plurality of first redistribution insulating layers 210. The plurality of chip pads 120 may be in contact with and connected to some of the plurality of first redistribution patterns 220. For example, the plurality of chip pads 120 may be connected to some of the uppermost ones of the first redistribution vias 224.

The semiconductor substrate 110 may include a semiconductor material, such as silicon (Si) and germanium (Ge). Also, the semiconductor substrate 110 may include compound semiconductor materials, such as silicon carbide (SiC), gallium arsenide (GaAs), indium arsenide (InAs), and indium phosphide (InP). The semiconductor substrate 110 may include a conductive region, for example, a well doped with impurities. The semiconductor substrate 110 may have various device isolation structures, such as a shallow trench isolation structure. The semiconductor device 112, including a plurality of various types of individual devices, may be formed on the active surface of the semiconductor substrate 110. The plurality of individual devices may include various microelectronic devices, for example, metal-oxide-semiconductor field effect transistors (MOSFET), such as complementary metal-oxide-semiconductor (CMOS) transistors, system large scale integration (LSI), active elements, passive elements, etc. The plurality of individual devices may be electrically connected to the conductive region of the semiconductor substrate 110. The semiconductor device 112 may further include a conductive wire or a conductive plug, which electrically connects at least two of the plurality of individual devices to each other or electrically connects the plurality of individual devices to the conductive region of the semiconductor substrate 110. Also, each of the plurality of individual devices may be electrically separated from individual devices adjacent thereto by an insulating film.

In some embodiments, the semiconductor chip 100 may include a logic element. For example, the semiconductor chip 100 may include a central processing unit (CPU) chip, a graphics processing unit (GPU) chip, or an application processor (AP) chip. In some embodiments, the semiconductor chip 100 may include a memory semiconductor chip including a memory element. For example, the memory element may include non-volatile memory elements, such as flash memory, phase-change random access memory (PRAM), magnetoresistive random access memory (MRAM), ferroelectric random access memory (FeRAM), and resistive random access memory (RRAM). The flash memory may include, for example, negative-AND (NAND) flash memory or vertical NAND (V-NAND) flash memory. In some embodiments, the memory element may include volatile memory elements, such as dynamic random access memory (DRAM) and static random access memory (SRAM). In some embodiments, when the semiconductor package 1 includes a plurality of semiconductor chips 100, at least one of the plurality of semiconductor chips 100 may include a CPU chip, a GPU chip, or an AP chip, and at least one other of the plurality of semiconductor chips 100 may include a memory semiconductor chip including a memory element.

In some embodiments, the semiconductor chip 100 may have a face down arrangement in which the first surface of the semiconductor chip 100 faces the first wiring structure 200 and may be thus attached to the upper surface of the first wiring structure 200. For example, the semiconductor chip 100 may be disposed on the first wiring structure 200 such that the plurality of chip pads 120 face the first wiring structure 200. In this case, the first surface of the semiconductor chip 100 may be referred to as the lower surface of the semiconductor chip 100 and the second surface of the semiconductor chip 100 may be referred to as the upper surface of the semiconductor chip 100.

The extension structure 300 may include an extension base layer 310 and a plurality of via structures 320. The extension structure 300 may have a mounting space 300G in which at least one semiconductor chip 100 is located. The plurality of via structures 320 may pass through the extension base layer 310 from the upper surface to the lower surface of the extension base layer 310. The extension structure 300 may include an embedded trace substrate (ETS), a printed circuit board (PCB), a ceramic substrate, a package manufacturing wafer, or an interposer. In some embodiments, the extension structure 300 may include two or more extension base layers 310 stacked on each other. For example, the extension structure 300 may include a multi-layer ETS or a multi-layer PCB.

The mounting space 300G may include an opening or cavity formed in the extension structure 300. The mounting space 300G may be formed in a partial region of the extension structure 300, for example, in a central region thereof in a plan view. The mounting space 300G may pass through the extension structure 300 from the upper surface to the lower surface of the extension structure 300.

The mounting space 300G may be located in the chip accommodation region CAR of the extension structure 300, and the extension base layer 310 and the plurality of via structures 320 may be located in the chip peripheral region CER. For example, in a plan view, the chip accommodation region CAR may include a region in which the mounting space 300G is located and the chip peripheral region CER may include a region in which the extension base layer 310 and the plurality of via structures 320 are located.

The extension base layer 310 may include phenolic resin, epoxy resin, and/or polyimide. The extension base layer 310 may include, for example, frame retardant 4 (FR-4), tetrafunctional epoxy, polyphenylene ether, epoxy/polyphenylene oxide, bismaleimide triazine (BT), Thermount, cyanate ester, polyimide, and/or liquid crystal polymer. In some embodiments, the extension base layer 310 may include a prepreg. For example, the extension base layer 310 may be in the form of a sheet that is made by impregnating a reinforcing material with a bonding material. The reinforcing material may include glass cloth, carbon cloth, non-woven glass fabric, or aramid cloth. The bonding material may include thermosetting resin, such as epoxy resin, polyester resin, and polyimide, or thermoplastic resin. In some embodiments, the extension base layer 310 may contain fillers. For example, the fillers may include a ceramic-based material having non-conductive insulating characteristics. In some embodiments, the fillers may include at least one of AIN, BN, Al₂O₃, SiC, and MgO. For example, the fillers may include silica fillers or alumina fillers. The average diameter of the fillers may be several μm to several tens of μm. Each of the plurality of via structures 320 may include a via connection pattern 322 and an extension via 324. The via connection pattern 322 may be disposed on the upper surface of the lower surface of the extension base layer 310. For example, when the extension structure 300 includes a plurality of extension base layers 310 stacked on each other, via connection patterns 322 may be provided in at least some locations, such as in a region of the upper surface of the uppermost one of the extension base layers 310, in a region of the lower surface of the lowermost one of the extension base layers 310, and in a region between two adjacent extension base layers 310 among the plurality of extension base layers 310. The extension via 324 may pass through at least one extension base layer 310 and extend in a vertical direction (e.g., Z direction). The extension via 324 may connect two via connection patterns 322 to each other which are at different vertical levels.

In some embodiments, the via connection pattern 322 may include electrolytically deposited (ED) copper foil, rolled-annealed (RA) copper foil, stainless steel foil, aluminum foil, ultra-thin copper foil, sputtered copper, copper alloys, or the like. In some embodiments, the extension via 324 may include copper (Cu) or an alloy containing copper (Cu). For example, the extension via 324 may have a structure in which copper (Cu) or an alloy of copper (Cu) is laminated on a seed layer that contains copper (Cu), titanium (Ti), titanium tungsten (TiW), titanium nitride (TiN), tantalum (Ta), tantalum nitride (TaN), chromium (Cr), Cu/Ti in which copper is laminated on titanium, or Cu/TiW in which copper is laminated on titanium tungsten, but the embodiment is not necessarily limited thereto.

Among the plurality of via connection patterns 322 of the plurality of via structures 320, each of the uppermost ones of the via connection patterns 322 may be referred to as an upper extension connection pad 322P1 and each of the lowermost ones of the via connection patterns 322 may be referred to as a lower extension connection pad 322P2. The lower surfaces of the plurality of lower extension connection pads 322P2 may be at a vertical level that is higher than the lower surface of the lowermost one of the extension base layers 310 and define a plurality of lower recesses 322R. The plurality of upper extension connection pads 322P1 might not be buried in the extension base layer 310 but may protrude upward from the upper surface of the extension base layer 310.

The semiconductor package 1 may further include a filling insulating layer 390 that fills the mounting space 300G. The filling insulating layer 390 may fill a space between the extension base layer 310 and at least one semiconductor chip 100 located in the mounting space 300G. The filling insulating layer 390 may fill the mounting space 300G and may cover the upper surface of the extension structure 300 and the upper surface of the semiconductor chip 100, for example, the second surface of the semiconductor chip 100. For example, the filling insulating layer 390 may include thermosetting resin, such as epoxy resin, polyester resin, and polyimide, or thermoplastic resin. In some embodiments, the filling insulating layer 390 may include fillers. In some embodiments, the filling insulating layer 390 might not include a reinforcing material, such as glass cloth, carbon cloth, non-woven glass fabric, and aramid cloth. For example, the filling insulating layer 390 may include ABF, FR-4, BT, or the like. Also, the filling insulating layer 390 may include a molding material, such as an epoxy molding compound (EMC), or a photosensitive material, such as a photoimagable encapsulant (PIE). In some embodiments, a portion of the filling insulating layer 390 may include an insulating material, such as a silicon oxide film, a silicon nitride film, and a silicon oxynitride film.

In some embodiments, the first surface of at least one semiconductor chip 100, the lower surface of the extension base layer 310, and the lower surface of the filling insulating layer 390 may be at the same vertical level and form a coplanar surface. For example, the bottom of the filling insulating layer 390 may be at a lower vertical level than the first surface of the at least one semiconductor chip 100 and the lower surface of the extension base layer 310, but may be at a higher vertical level than the lower surfaces of the plurality of chip pads 120.

The plurality of via connection patterns 322 of the extension structure 300 may form a plurality of wiring layers. The wiring layer refers to where an electrical path extending along a horizontal plane formed in a first horizontal direction (e.g., X direction) and a second horizontal direction (e.g., Y direction) may be formed. For example, the extension structure 300 may have one more wiring layers than the number of extension base layers 310 of the extension structure 300. For example, the plurality of wiring layers may include a first wiring layer L1, a second wiring layer L2, a third wiring layer L3, and a fourth wiring layer L4, which are at different vertical levels. The first wiring layer L1, the second wiring layer L2, the third wiring layer L3, and the fourth wiring layer LA may be sequentially arranged from the upper end to the lower end of the extension structure 300. When the extension structure 300 includes three extension base layers 310 and constitute four wiring layers including the first wiring layer L1, the second wiring layer L2, the third wiring layer L3, and the fourth wiring layer L4, the uppermost ones of the plurality of via connection patterns 322 may form the first wiring layer L1 and the lowermost ones of the plurality of via connection patterns 322 may form the fourth wiring layer L4. Each of the via connection patterns 322 constituting the first wiring layer L1 may include the upper extension connection pad 322P1 and each of the via connection patterns 322 constituting the fourth wiring layer L4 may include the lower extension connection pad 322P2.

Each of the via connection patterns 322 constituting each of the first wiring layer L1, the second wiring layer L2, and the third wiring layer L3 may have a first thickness Tl and each of the via connection patterns 322 constituting the fourth wiring layer L4 may have a second thickness T2. The first thickness T1 may be greater than the second thickness T2. The second thickness T2 may be less than the first thickness T1 by about 2 μm to about 5 μm. For example, the first thickness T1 may be about 15 μm to about 20 μm. Also, the second thickness T2 may be less than the first thickness Tl and may be about 10 μm to about 15 μm. The thickness of the via connection patterns 322 constituting the first wiring layer L1, the thickness of the via connection patterns 322 constituting the second wiring layer L2, and the thickness of the via connection patterns 322 constituting the third wiring layer L3 may be substantially equal to each other, but the embodiment is not necessarily limited thereto. For example, the thickness of the via connection patterns 322 constituting the first wiring layer L1 may be different from the thickness of the via connection patterns 322 constituting the second wiring layer L2 and the thickness of the via connection patterns 322 constituting the third wiring layer L3. However, the thickness of the via connection patterns 322 constituting the first wiring layer L1, the thickness of the via connection patterns 322 constituting the second wiring layer L2, and the thickness of the via connection patterns 322 constituting the third wiring layer L3 may all have a value that is greater than the second thickness T2.

At least some of the plurality of via connection patterns 322 may be buried in the extension base layer 310. In some embodiments, the via connection patterns 322 constituting the first wiring layer L1 might not be buried in the extension base layer 310, but the via connection patterns 322 constituting the second wiring layer L2, the third wiring layer L3, and the fourth wiring layer LA may be buried in the extension base layer 310. In some embodiments, the lower surface of the via connection patterns 322 constituting the fourth wiring layer L4 may be at a higher vertical level than the lower surface of the extension base layer 310 in which the via connection patterns 322 constituting the fourth wiring layer L4 are buried. The lower surface of the via connection patterns 322 constituting the second wiring layer L2 may be at the same vertical level as the lower surface of the extension base layer 310 in which the via connection patterns 322 constituting the second wiring layer L2 are buried. The lower surface of the via connection patterns 322 constituting the third wiring layer L3 may be at the same vertical level as the lower surface of the extension base layer 310 in which the via connection patterns 322 constituting the third wiring layer L3 are buried.

The extension structure 300 may have a plurality of lower recesses 322R formed in the lower surface thereof. The plurality of lower recesses 322R may be defined by the via connection patterns 322 and the extension base layer 310 constituting the fourth wiring layer L4. Each of the lower recesses 322R may have a first depth D1 from the bottom of the extension structure 300. The first depth D1 may be about 2 μm to about 5 μm.

The via connection patterns 322 constituting the fourth wiring layer L4, for example, the plurality of lower extension connection pads 322P2, may include a plurality of first lower connection pads 322P2C adjacent to the mounting space 300G and a plurality of second lower connection pads 322P2E spaced apart from the mounting space 300G with a plurality of first lower connection pads 322P2C disposed therebetween. In a plan view, the plurality of first lower connection pads 322P2C may be arranged around the mounting space 300G and may at least partially surround the mounting space 300G. In a plan view, the plurality of second lower connection pads 322P2E may at least partially surround the plurality of first lower connection pads 322P2C.

Each of the plurality of first lower connection pads 322P2C may have a pad trench 322T. The pad trench 322T may pass through the first lower connection pad 322P2C such that the first lower connection pads 322P2C are not separated into two parts, and may be spaced apart from the edge of the first lower connection pad 322P2C in a plan view. The pad trench 322T may be located in the first lower connection pad 322P2C between the extension via 324 and the first redistribution via 224 connected to the first lower connection pad 322P2C and the mounting space 300G. The pad trench 322T may extend from the upper surface to the lower surface of the first lower connection pad 322P2C and extend into the first redistribution insulating layer 210 in contact with the first lower connection pad 322P2C.

The extension base layer 310, in which the plurality of lower extension connection pads 322P2 are buried, includes a base dam 310D that fills the pad trench 322T of the first lower connection pad 322P2C. The base dam 310D may have a first horizontal width W1. For example, the first horizontal width W1 may be about 10 μm to about 30 μm. The base dam 310D may protrude downward from the lower surface of the first lower connection pad 322P2C and extend into the first redistribution insulating layer 210. The height of a protruding region of the base dam 310D that protrudes downward from the lower surface of the first lower connection pad 322P2C may correspond to the first depth D1. For example, the height of the protruding region of the base dam 310D that protrudes downward from the lower surface of the first lower connection pad 322P2C may be about 2 μm to about 5 μm.

The bottom of the extension base layer 310, in which the plurality of lower extension connection pads 322P2 are buried, and the lower surface of the base dam 310D may be at the same vertical level. In some embodiments, the bottom of the extension base layer 310 in which the plurality of lower extension connection pads 322P2 are buried, the lower surface of the base dam 310D, and the first surface of the semiconductor chip 100 may be at the same vertical level.

The filling insulating layer 390 may include a bleeding portion 390BD that extends from the mounting space 300G along the lower surface of the extension structure 300 and/or the first surface of the semiconductor chip 100. In the bleeding portion 390BD, a portion disposed on the lower surface of the extension structure 300 may be referred to as a first bleeding portion 390BDa and a portion disposed on the first surface of the semiconductor chip 100 may be referred to as a second bleeding portion 390BDb. In some embodiments, the bleeding portion 390BD may include only the first bleeding portion 390BDa and might not include the second bleeding portion 390BDb.

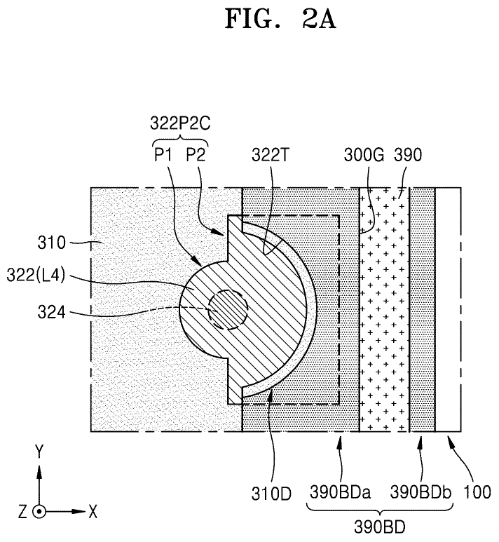

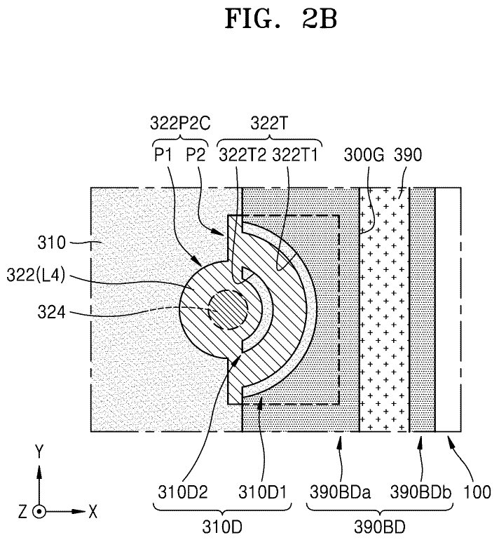

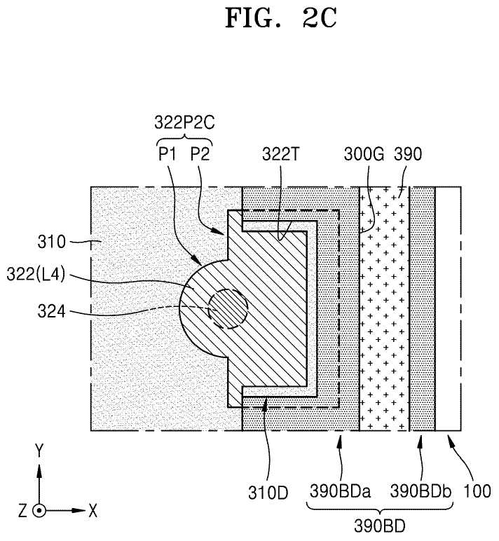

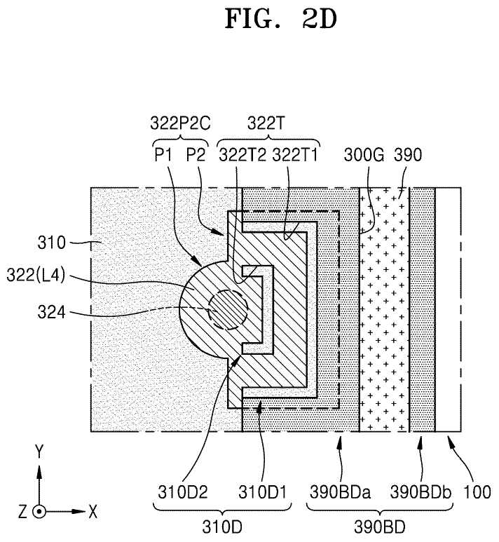

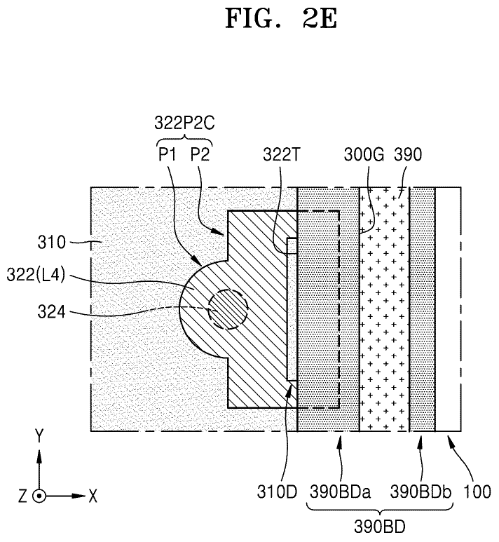

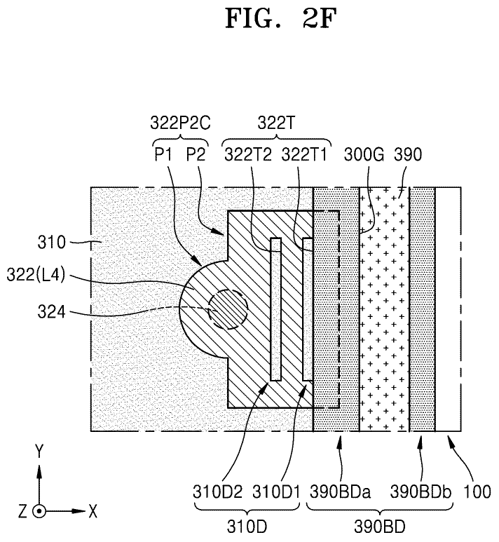

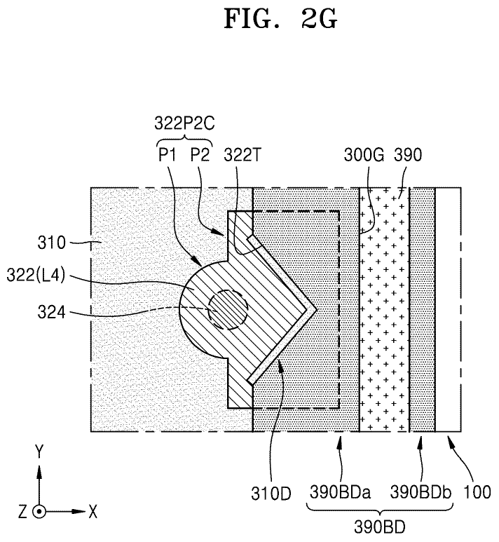

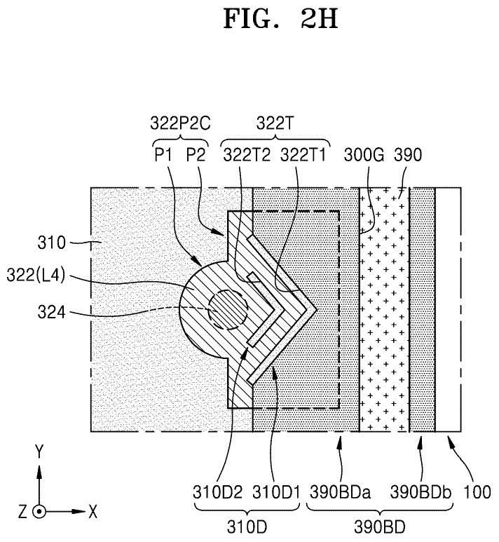

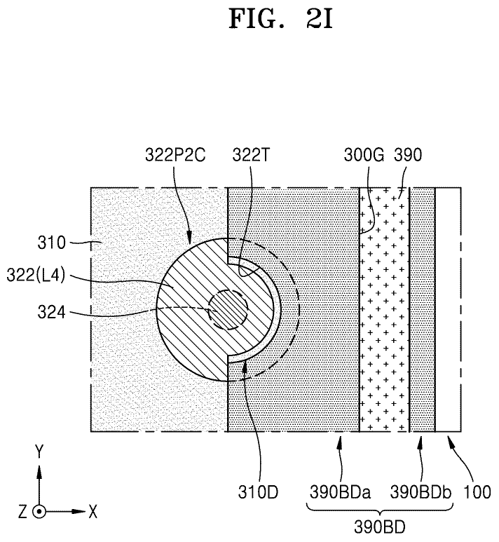

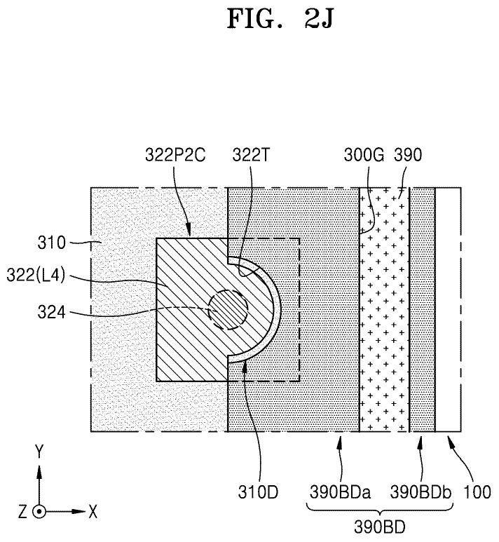

The first bleeding portion 390BDa may extend from the mounting space 300G along the lower surface of the extension structure 300, extend into the lower recess 322R, and come into contact with the first lower connection pad 322P2C. The bleeding portion 390BD including the first bleeding portion 390BDa and the second bleeding portion 390BDb may extend into the lower recess 322R defined by the extension base layer 310 and the lower surface of the first lower connection pad 322P2C, but might not extend into the lower recess 322R defined by the extension base layer 310 and the lower surface of the second lower connection pads 322P2E. FIG. 1D shows that the first bleeding portion 390BDa is not in contact with the base dam 310D in the lower recess 322R. However, this is an example, and the embodiment is not necessarily limited thereto. For example, the first bleeding portion 390BDa may be in contact with the base dam 310D inside the lower recess 322R. The first bleeding portion 390BDa may be in contact with a portion of the lower surface of the first lower connection pad 322P2C which is close to the mounting space 300G on the basis of the base dam 310D, but might not be in contact with a portion of the lower surface of the first lower connection pad 322P2C which is far from the mounting space 300G on the basis of the base dam 310D. This is described below in detail with reference to FIGS. 2A to 2J.

The thickness of the bleeding portion 390BD including the first bleeding portion 390BDa and the second bleeding portion 390BDb may be less than the thickness of each of the plurality of chip pads 120. The second bleeding portion 390BDb may extend from the mounting space 300G along the first surface of the semiconductor chip 100. Also, the second bleeding portion 390BDb might not be in contact with the plurality of chip pads 120 or may be in contact with only a portion of the side surfaces of some of the plurality of chip pads 120. However, the second bleeding portion 390BDb might not be in contact with the lower surfaces of the plurality of chip pads 120.

The pad trench 322T and the base dam 310D filling the pad trench 322T are located between the first redistribution via 224 connected to the first lower connection pad 322P2C and the mounting space 300G. Accordingly, even if the bleeding portion 390BD covers a portion of the lower surface of the first lower connection pad 322P2C, the base dam 310D may prevent the bleeding portion 390BD from extending to the first redistribution via 224.

The second wiring structure 400 may include a second redistribution insulating layer 410 and a plurality of second redistribution patterns 420. The plurality of second redistribution patterns 420 may include a plurality of second redistribution line patterns 422 and a plurality of second redistribution vias 424. In some embodiments, the plurality of second redistribution patterns 420 may further include a plurality of second redistribution seed layers. The second redistribution insulating layer 410 and the plurality of second redistribution patterns 420 of the second wiring structure 400 are generally similar to the first redistribution insulating layer 210 and the plurality of first redistribution patterns 220 of the first wiring structure 200, and thus, to the extent that an element is not described in detail with respect to this figure, it may be understood that the element is at least similar to a corresponding element that has been described elsewhere within the present disclosure.

In some embodiments, the thickness of the second wiring structure 400 may be less than the thickness of the first wiring structure 200. For example, the first wiring structure 200 may have a thickness of about 30 μm to about 50 μm. Also, the second wiring structure 400 may be thinner than the first wiring structure 200 and have a thickness of about 20 μm to about 40 μm. In some embodiments, the second wiring structure 400 may include a plurality of second redistribution insulating layers 410 stacked on each other. For example, the number of second redistribution insulating layers 410 stacked on each other in the second wiring structure 400 may be less than the number of first redistribution insulating layers 210 stacked on each other in the first wiring structure 200. The upper surface of the filling insulating layer 390 and the lower surface of the second redistribution insulating layer 410 may be at the same vertical level.

The plurality of second redistribution vias 424 may pass through the at least one second redistribution insulating layer 410 and may then contact and be connected to some of the plurality of second redistribution line patterns 422. In some embodiments, the plurality of second redistribution vias 424 may each have a tapered shape extending from the bottom to the top with an increasing horizontal width. For example, the horizontal width of the plurality of second redistribution vias 424 may increase away from the at least one semiconductor chip 100. The lowermost ones of the plurality of second redistribution vias 424 may be connected to the upper surfaces of the via structures 320. In some embodiments, the lowermost ones of the plurality of second redistribution vias 424 may pass through the filling insulating layer 390 and be connected to the upper surfaces of the via structures 320.

In some embodiments, at least some of the plurality of second redistribution line patterns 422 may be formed together with some of the plurality of second redistribution vias 424 to form integrated bodies. For example, the second redistribution line pattern 422 and the second redistribution via 424 in contact with the lower surface of the second redistribution line pattern 422, for example, the second redistribution via 424 extending from the lower surface of the second redistribution line pattern 422, may be formed together to form an integrated body. For example, the horizontal width of each of the plurality of second redistribution vias 424 may decrease in a direction away from the second redistribution line pattern 422 integrated therewith. The second redistribution seed layer may cover lower portions of the second redistribution line pattern 422 and the second redistribution via 424 which are integrated with each other. For example, the second redistribution seed layer may cover the lower surface of the second redistribution line pattern 422 and the side and lower surfaces of the second redistribution via 424, among surfaces of the second redistribution line pattern 422 and the second redistribution via 424 that are integrated with each other. The second redistribution seed layer might not cover the side and upper surfaces of the second redistribution line pattern 422.

The second wiring structure 400 may include a plurality of upper connection pads PAD-U disposed on the upper surface of the second wiring structure 400. In some embodiments, each of the plurality of upper connection pads PAD-U may include a portion of the second redistribution line pattern 422 and an upper connection pad layer 430 that covers the upper surface of the portion of the second redistribution line pattern 422. The upper connection pad layer 430 may include a first upper metal layer 432 and a second upper metal layer 434, which are sequentially stacked on the second redistribution line pattern 422. In some embodiments, the first upper metal layer 432 may include nickel (Ni) and the second upper metal layer 434 may include gold (Au), but the embodiment is not necessarily limited thereto.

In the semiconductor package 1, according to the inventive concept, the extension structure 300 includes the base dam 310D. Accordingly, even if the filling insulating layer 390 includes the bleeding portion 390BD extending from the mounting space 300G along the lower surface of the extension structure 300, the bleeding portion 390BD may be prevented from extending to a portion of the lower extension connection pad 322P2 that is in contact with the first redistribution via 224. Accordingly, a first redistribution pattern 220 of the first wiring structure 200 and a via structure 320 of the extension structure 300 may be prevented from being short-circuited by the bleeding portion 390BD, and thus, the reliability of the electrical connection of the semiconductor package 1 may be increased.

FIGS. 2A to 2J are enlarged plan views showing a first lower connection pad 322P2C and a surrounding region thereof in a semiconductor package, which is an FOPLP, according to embodiments. Specifically, FIGS. 2A to 2J are enlarged plan views of the extension structure 300 of the semiconductor package 1 shown in FIGS. 1A to 1D when viewed from below.

Referring to FIG. 2A, the first lower connection pad 322P2C, which is the via connection patterns 322 constituting the fourth wiring layer L4, may be located adjacent to the mounting space 300G. The first lower connection pad 322P2C may be buried in the extension base layer 310. The semiconductor chip 100 and the filling insulating layer 390 at least partially surrounding the semiconductor chip 100 may fill the mounting space 300G. In some embodiments, the first lower connection pad 322P2C may have a shape in which a semicircle and a rectangle are coupled to each other in a plan view. For example, the first lower connection pad 322P2C may include a first portion P1 having a semicircular shape and a second portion P2 having a rectangular shape in a plan view. The first portion P1 and the second portion P2 of the first lower connection pad 322P2C may be integrated with each other. The second portion P2 may be located between the first portion P1 and the mounting space 300G. For example, the first portion P1 may be located far from the mounting space 300G, but the second portion P2 may be located close to the mounting space 300G. In some embodiments, the extension via 324 connected to the first lower connection pad 322P2C may overlap both the first portion P1 and the second portion P2 in the vertical direction (e.g., Z direction). For example, a portion of the extension via 324 may overlap the first portion P1 in the vertical direction (e.g., Z direction) and the other portion of the extension via 324 may overlap the second portion P2. In some embodiments, the radius of the first portion P1 having a semicircular shape may be less than the length of a short side of the second portion P2 having a rectangular shape.

The first lower connection pad 322P2C may have a pad trench 322T. The extension base layer 310, in which the first lower connection pad 322P2C is buried, may include the base dam 310D that fills the pad trench 322T. The pad trench 322T may pass through the first lower connection pad 322P2C such that the first lower connection pads 322P2C are not separated into two parts, and may be spaced apart from the edge of the first lower connection pad 322P2C in a plan view. The pad trench 322T may be located in the first lower connection pad 322P2C between the mounting space 300G and the extension via 324 connected to the first lower connection pad 322P2C. The pad trench 322T may be located in the second portion P2 of the first lower connection pad 322P2C.

In some embodiments, the pad trench 322T and the base dam 310D filling the pad trench 322T may have an arc shape in a plan view. In a plan view, the center of the arc shape of the pad trench 322T and the base dam 310D may substantially coincide with the center of the semicircular shape of the first portion P1 of the first lower connection pad 322P2C, but the embodiment is not necessarily limited thereto. The pad trench 322T and the base dam 310D may at least partially surround a region of the extension via 324 that faces the mounting space 300G in a plan view. In a plan view, the radius of the arc shape of the pad trench 322T and the base dam 310D filling the pad trench 322T may be greater than the radius of the semicircular shape of the first portion P1 of the first lower connection pad 322P2C.

In some embodiments, the extension via 324 connected to the first lower connection pad 322P2C may have a circular shape in a plan view. In a plan view, the center of the circular shape of the extension via 324 connected to the first lower connection pad 322P2C may substantially coincide with the center of the arc shape of the pad trench 322T and the base dam 310D and/or the center of the semicircular shape of the first portion P1 of the first lower connection pad 322P2C, but the embodiment is not necessarily limited thereto. In a plan view, the radius of the circular shape of the extension via 324 connected to the first lower connection pad 322P2C may be less than the radius of the arc shape of the pad trench 322T and the base dam 310D filling the pad trench 322T and the radius of the semicircular shape of the first portion P1 of the first lower connection pad 322P2C.

The filling insulating layer 390 may include the bleeding portion 390BD extending from the mounting space 300G to lower sides of the extension structure 300 and/or the semiconductor chip 100. In the bleeding portion 390BD, a portion disposed below the extension structure 300 may be referred to as a first bleeding portion 390BDa and a portion disposed below the semiconductor chip 100 may be referred to as a second bleeding portion 390BDb. In some embodiments, the bleeding portion 390BD may include only the first bleeding portion 390BDa and might not include the second bleeding portion 390BDb. During a process of forming the filling insulating layer 390 that fills the mounting space 300G, the bleeding portion 390BD may be formed as a portion of the material forming the filling insulating layer 390 permeates the lower sides of the extension structure 300 and/or the semiconductor chip 100 from the mounting space 300G.

The bleeding portion 390BD may extend from the mounting space 300G to the lower side of the extension structure 300 and may cover a portion of the first lower connection pad 322P2C. The bleeding portion 390BD may extend from the mounting space 300G to the lower side of the extension structure 300 and may cover a portion of the first lower connection pad 322P2C. However, the bleeding portion 390BD might not extend further due to the base dam 310D and thus might not cover the other portion of the first lower connection pad 322P2C. For example, the bleeding portion 390BD may cover a portion of the second portion P2 of the first lower connection pad 322P2C which is adjacent to the mounting space 300G on the basis of the base dam 310D, but might not cover the first portion P1 and the other portion of the second portion P2 which is spaced far away from the mounting space 300G on the basis of the base dam 310D. In a plan view, the bleeding portion 390BD might not overlap the extension via 324 and a portion of the first lower connection pad 322P2C adjacent to the extension via 324.

Referring to FIG. 2B, a pad trench 322T of a first lower connection pad 322P2C may include a first pad trench 322T1 and a second pad trench 322T2, which are spaced apart from each other. A base dam 310D of an extension base layer 310, in which the first lower connection pad 322P2C is buried, may include a first base dam 310D1 filling the first pad trench 322T1 and a second base dam 310D2 filling the second pad trench 322T2. The first base dam 310D1 filling the first pad trench 322T1 and the second base dam 310D2 filling the second pad trench 322T2 may be spaced apart from each other, in a plan view, between a first redistribution via 224 connected to the first lower connection pad 322P2C and a mounting space 300G.

In some embodiments, the first pad trench 322T1, the first base dam 310D1 filling the first pad trench 322T1, the second pad trench 322T2, and the second base dam 310D2 filling the second pad trench 322T2 may each have an arc shape. In a plan view, the center of the arc shape of the first pad trench 322T1 and the first base dam 310D1 filling the first pad trench 322T1 may substantially coincide with the center of the arc shape of the second pad trench 322T2 and the second base dam 310D2 filling the second pad trench 322T2. In a plan view, the radius of the arc shape of the first pad trench 322T1 and the first base dam 310D1 filling the first pad trench 322T1 may be greater than the radius of the arc shape of the second pad trench 322T2 and the second base dam 310D2 filling the second pad trench 322T2. In a plan view, the second pad trench 322T2 and the second base dam 310D2 may at least partially surround a region of the extension via 324 facing the mounting space 300G, and the first pad trench 322T1 and the first base dam 310D1 may at least partially surround a region of the second pad trench 322T2 and a region of the second base dam 310D2 facing the mounting space 300G.

When the bleeding portion 390BD extends from the mounting space 300G to the lower side of the extension structure 300 while covering a portion of the first lower connection pad 322P2C, even if the bleeding portion 390BD extends while covering the first base dam 310D1, the bleeding portion 390BD might not extend further due to the second base dam 310D2. Therefore, the bleeding portion 390BD might not cover the first portion P1 and the other portion of the second portion P2 that is spaced far away from the mounting space 300G on the basis of the second base dam 310D2.

Referring to FIG. 2C, in some embodiments, a pad trench 322T and a base dam 310D filling the pad trench 322T may have a U-shape. The pad trench 322T and the base dam 310D may at least partially surround a region of the extension via 324 that faces the mounting space 300G in a plan view.

Referring to FIG. 2D, a pad trench 322T of a first lower connection pad 322P2C may include a first pad trench 322T1 and a second pad trench 322T2, which are spaced apart from each other. A base dam 310D of an extension base layer 310, in which the first lower connection pad 322P2C is buried, may include a first base dam 310D1 filling the first pad trench 322T1 and a second base dam 310D2 filling the second pad trench 322T2.

In some embodiments, the first pad trench 322T1, the first base dam 310D1 filling the first pad trench 322T1, the second pad trench 322T2, and the second base dam 310D2 filling the second pad trench 322T2 may each have a U-shape. In a plan view, the second pad trench 322T2 and the second base dam 310D2 may at least partially surround a region of the extension via 324 facing the mounting space 300G, and the first pad trench 322T1 and the first base dam 310D1 may at least partially surround a region of the second pad trench 322T2 and a region of the second base dam 310D2 facing the mounting space 300G.

Referring to FIG. 2E, in some embodiments, a pad trench 322T and a base dam 310D filling the pad trench 322T may have a bar shape. The pad trench 322T and the base dam 310D may have a bar shape extending along the edge of the mounting space 300G adjacent thereto between the mounting space 300G and the extension via 324 in a plan view.

Referring to FIG. 2F, a pad trench 322T of a first lower connection pad 322P2C may include a first pad trench 322T1 and a second pad trench 322T2, which are spaced apart from each other. A base dam 310D of an extension base layer 310, in which the first lower connection pad 322P2C is buried, may include a first base dam 310D1 filling the first pad trench 322T1 and a second base dam 310D2 filling the second pad trench 322T2.

In some embodiments, the first pad trench 322T1, the first base dam 310D1 filling the first pad trench 322T1, the second pad trench 322T2, and the second base dam 310D2 filling the second pad trench 322T2 may each have a bar shape.

FIG. 2F shows that the extension length of the bar shape of the first pad trench 322T1 and the first base dam 310D1 is the same as the extension length of the bar shape of the second pad trench 322T2 and the second base dam 310D2. However, this is an example, and the embodiment is not necessarily limited thereto. In some embodiments, the extension length of the bar shape of the first pad trench 322T1 and the first base dam 310D1 may be greater than the extension length of the bar shape of the second pad trench 322T2 and the second base dam 310D2.

Referring to FIG. 2G, in some embodiments, a pad trench 322T and a base dam 310D filling the pad trench 322T may have a V-shape. The pad trench 322T and the base dam 310D may at least partially surround a region of the extension via 324 that faces the mounting space 300G in a plan view.

Referring to FIG. 2H, a pad trench 322T of a first lower connection pad 322P2C may include a first pad trench 322T1 and a second pad trench 322T2, which are spaced apart from each other. A base dam 310D of an extension base layer 310, in which the first lower connection pad 322P2C is buried, may include a first base dam 310D1 filling the first pad trench 322T1 and a second base dam 310D2 filling the second pad trench 322T2.

In some embodiments, the first pad trench 322T1, the first base dam 310D1 filling the first pad trench 322T1, the second pad trench 322T2, and the second base dam 310D2 filling the second pad trench 322T2 may each have a V-shape. In a plan view, the second pad trench 322T2 and the second base dam 310D2 may at least partially surround a region of the extension via 324 facing the mounting space 300G, and the first pad trench 322T1 and the first base dam 310D1 may at least partially surround a region of the second pad trench 322T2 and a region of the second base dam 310D2 facing the mounting space 300G.

Referring to FIG. 2I, a first lower connection pad 322P2C may have a circular shape in a plan view. The first lower connection pad 322P2C may have a pad trench 322T. The extension base layer 310, in which the first lower connection pad 322P2C is buried, may include the base dam 310D that fills the pad trench 322T. FIG. 2I shows that the pad trench 322T and the base dam 310D filling the pad trench 322T have an arc shape that may be similar to that of the pad trench 322T and the base dam 310D filling the pad trench 322T shown in FIG. 2A. However, this is an example, and the embodiment is not necessarily limited thereto. For example, the pad trench 322T and the base dam 310D may have one of the U-shape, the bar shape, and the V-shape of the pad trench 322T and the base dam 310D as shown in FIGS. 2C, 2E, and 2I. Also, the pad trench 322T and the base dam 310D may have one of the double U-shape, the double bar shape, and the double V-shape of the pad trench 322T and the base dam 310D as shown in FIGS. 2B, 2F, and 2H.

Referring to FIG. 2J, a first lower connection pad 322P2C may have a rectangular shape or a square shape in a plan view. The first lower connection pad 322P2C may have a pad trench 322T. The extension base layer 310, in which the first lower connection pad 322P2C is buried, may include the base dam 310D that fills the pad trench 322T. FIG. 2J shows that the pad trench 322T and the base dam 310D filling the pad trench 322T have an arc shape similar to that of the pad trench 322T and the base dam 310D filling the pad trench 322T of FIG. 2A. However, this is an example, and the embodiment is not necessarily limited thereto. For example, the pad trench 322T and the base dam 310D may have one of the U-shape, the bar shape, and the V-shape of the pad trench 322T and the base dam 310D as shown in FIGS. 2C, 2E, and 2I. Also, the pad trench 322T and the base dam 310D may have one of the double U-shape, the double bar shape, and the double V-shape of the pad trench 322T and the base dam 310D as shown in FIGS. 2B, 2F, and 2H.

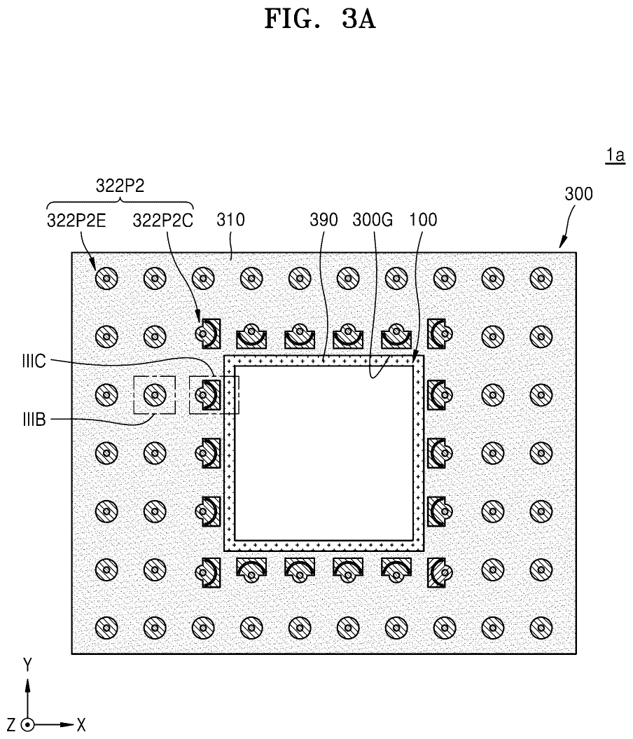

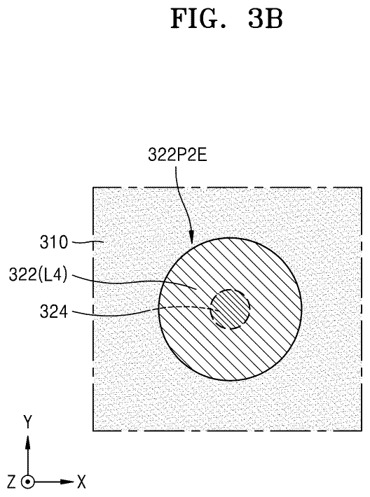

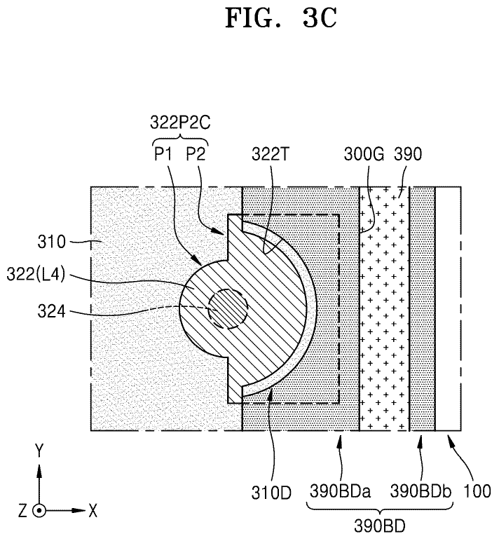

FIG. 3A is a plan view of a semiconductor package la, which is an FOPLP, according to embodiments, FIG. 3B is an enlarged plan view showing a second lower connection pad 322P2E and a surrounding region thereof, and FIG. 3C is an enlarged plan view showing a first lower connection pad 322P2C and a surrounding region thereof.

Referring to FIGS. 3A to 3C together, an extension structure 300 of the semiconductor package la includes a plurality of first lower extension connection pads 322P2, which are via connection patterns 322 constituting a fourth wiring layer L4. The plurality of first lower connection pads 322P2C may be buried in an extension base layer 310. A semiconductor chip 100 and a filling insulating layer 390 at least partially surrounding the semiconductor chip 100 may fill a mounting space 300G.

The plurality of first lower extension connection pads 322P2 may include a plurality of first lower connection pads 322P2C adjacent to the mounting space 300G and a plurality of second lower connection pads 322P2E spaced apart from the mounting space 300G with the plurality of first lower connection pads 322P2C therebetween. In a plan view, the plurality of first lower connection pads 322P2C may be arranged around the mounting space 300G and at least partially surround the mounting space 300G. In a plan view, the plurality of second lower connection pads 322P2E may at least partially surround the plurality of first lower connection pads 322P2C.

In some embodiments, in a plan view, the plurality of first lower connection pads 322P2C may extend in one row along the edge of the mounting space 300G. For example, only one first lower connection pad 322P2C, among the plurality of first lower connection pads 322P2C, may be located between the mounting space 300G and each of the plurality of second lower connection pads 322P2E. The plurality of second lower connection pads 322P2E may at least partially surround the plurality of first lower connection pads 322P2C at least partially surrounding the mounting space 300G in a plan view. In a plan view, some of the plurality of second lower connection pads 322P2E may be arranged along the edge of the semiconductor package 1a.

In some embodiments, each of the second lower connection pads 322P2E may have a circular shape or an elliptical shape in a plan view. All of extension vias 324 connected to the second lower connection pads 322P2E may overlap the second lower connection pads 322P2E in the vertical direction (e.g., Z direction).

FIGS. 3A and 3C show that the first lower connection pad 322P2C, the pad trench 322T, and the base dam 310D are substantially the same as the first lower connection pad 322P2C, the pad trench 322T, and the base dam 310D of FIG. 2A. However, this is an example, and the embodiment is not necessarily limited thereto. For example, the first lower connection pad 322P2C, the pad trench 322T, and the base dam 310D may include the first lower connection pad 322P2C, the pad trench 322T, and the base dam 310D shown in any one of FIGS. 2B to 2J.

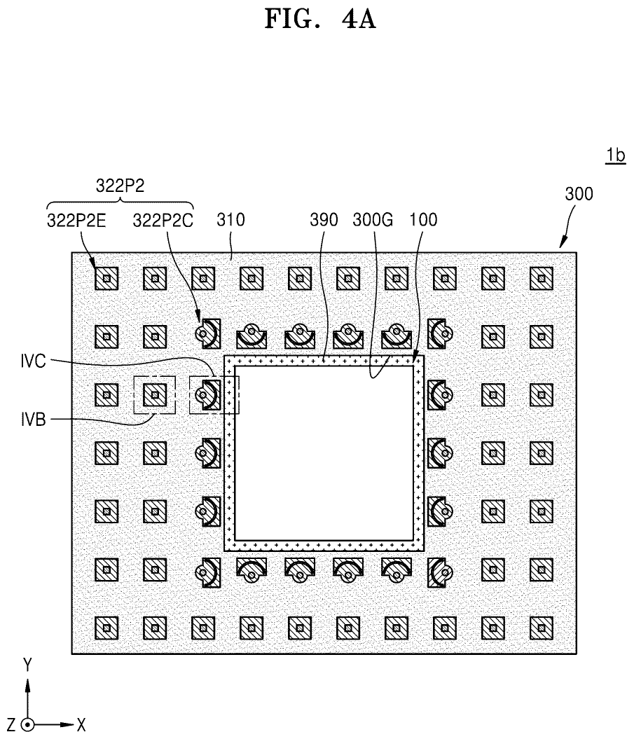

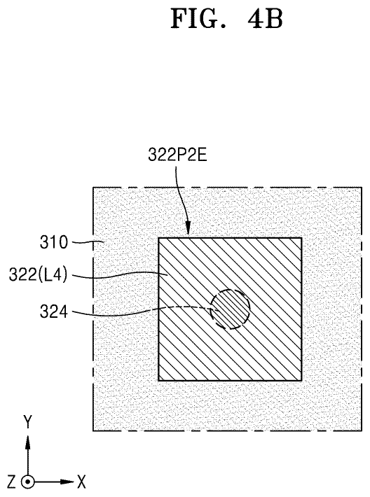

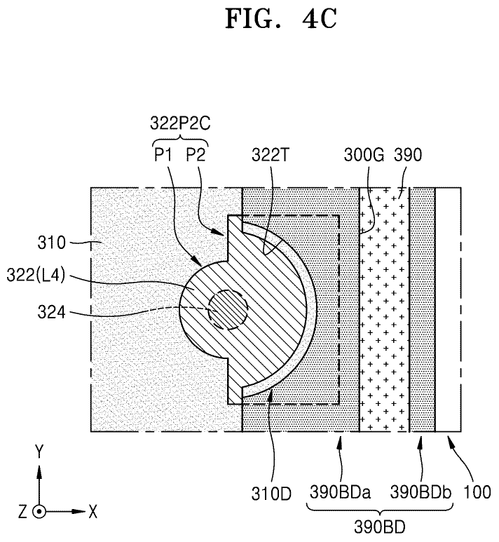

FIG. 4A is a plan view of a semiconductor package 1b, which is an FOPLP, according to embodiments, FIG. 4B is an enlarged plan view showing a second lower connection pad 322P2E and a surrounding region thereof, and FIG. 4C is an enlarged plan view showing a first lower connection pad 322P2C and a surrounding region thereof.

Referring to FIGS. 4A to 4C together, an extension structure 300 of the semiconductor package 1b includes a plurality of first lower extension connection pads 322P2, which are via connection patterns 322 constituting a fourth wiring layer L4. The plurality of first lower connection pads 322P2C may be buried in an extension base layer 310. A semiconductor chip 100 and a filling insulating layer 390 at least partially surrounding the semiconductor chip 100 may fill a mounting space 300G.

The plurality of first lower extension connection pads 322P2 may include a plurality of first lower connection pads 322P2C adjacent to the mounting space 300G and a plurality of second lower connection pads 322P2E spaced apart from the mounting space 300G with the plurality of first lower connection pads 322P2C therebetween. In a plan view, the plurality of first lower connection pads 322P2C may be arranged around the mounting space 300G and at least partially surround the mounting space 300G. In a plan view, the plurality of second lower connection pads 322P2E may at least partially surround the plurality of first lower connection pads 322P2C.

In some embodiments, each of the second lower connection pads 322P2E may have a rectangular shape or a square shape in a plan view. All of extension vias 324 connected to the second lower connection pads 322P2E may overlap the second lower connection pads 322P2E in the vertical direction (e.g., Z direction).

FIGS. 4A and 4C show that the first lower connection pad 322P2C, the pad trench 322T, and the base dam 310D are substantially the same as the first lower connection pad 322P2C, the pad trench 322T, and the base dam 310D of FIG. 2A. However, this is an example, and the embodiment is not necessarily limited thereto. For example, the first lower connection pad 322P2C, the pad trench 322T, and the base dam 310D may include the first lower connection pad 322P2C, the pad trench 322T, and the base dam 310D shown in any one of FIGS. 2B to 2J.

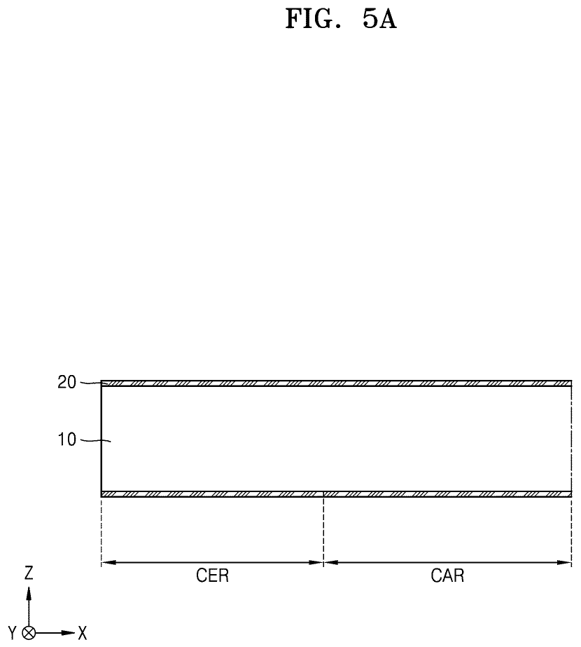

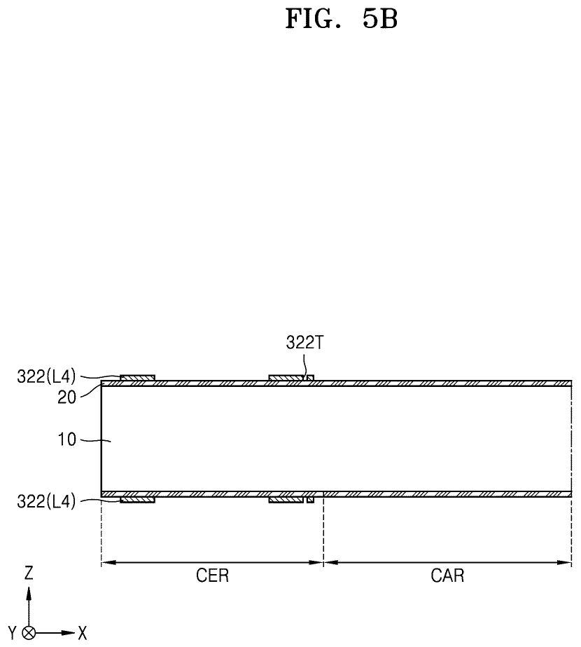

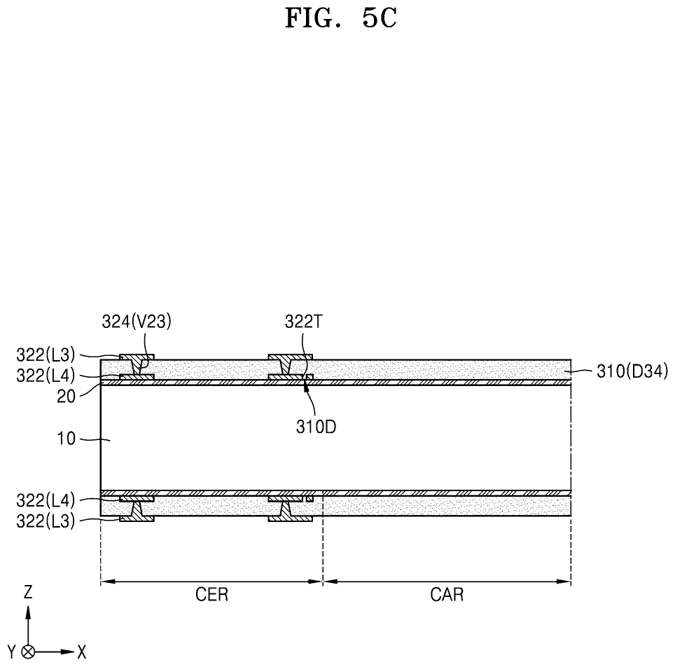

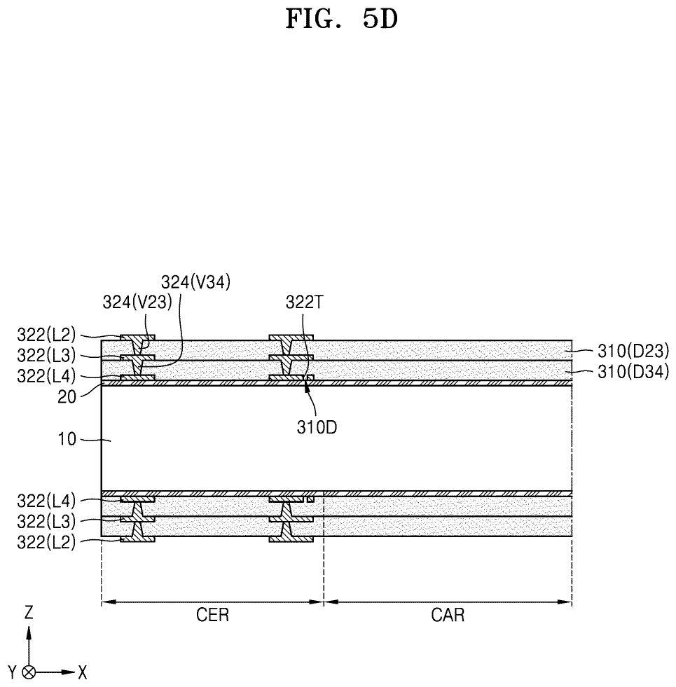

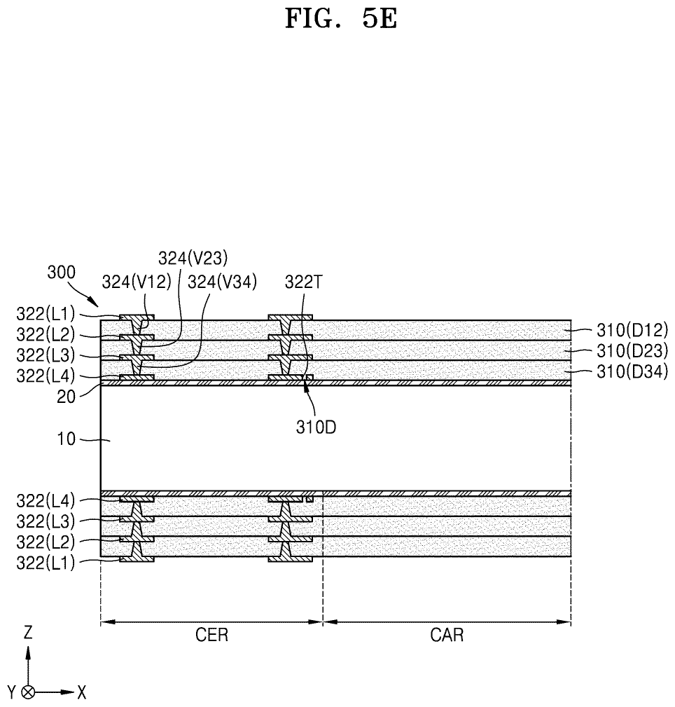

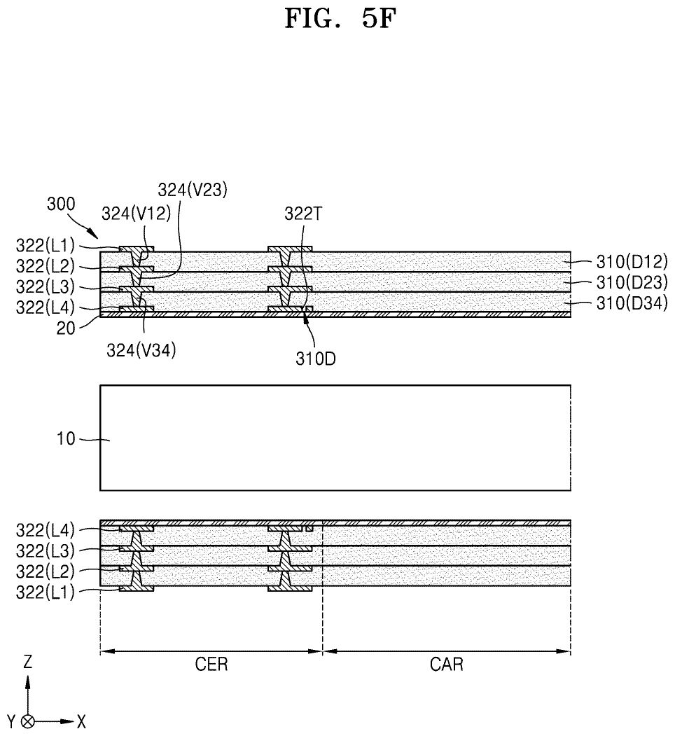

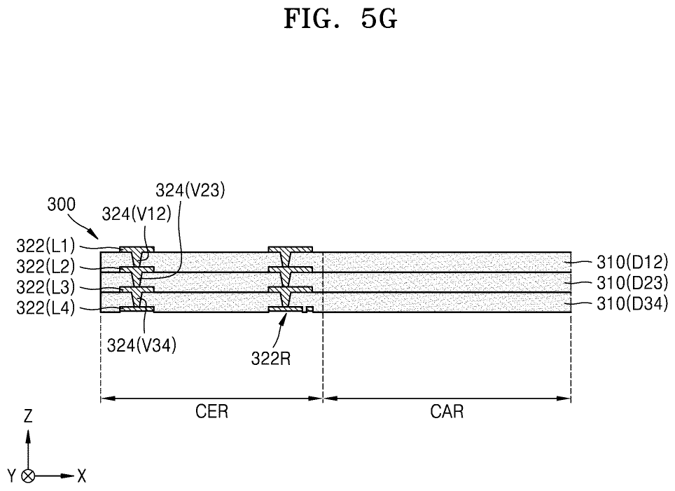

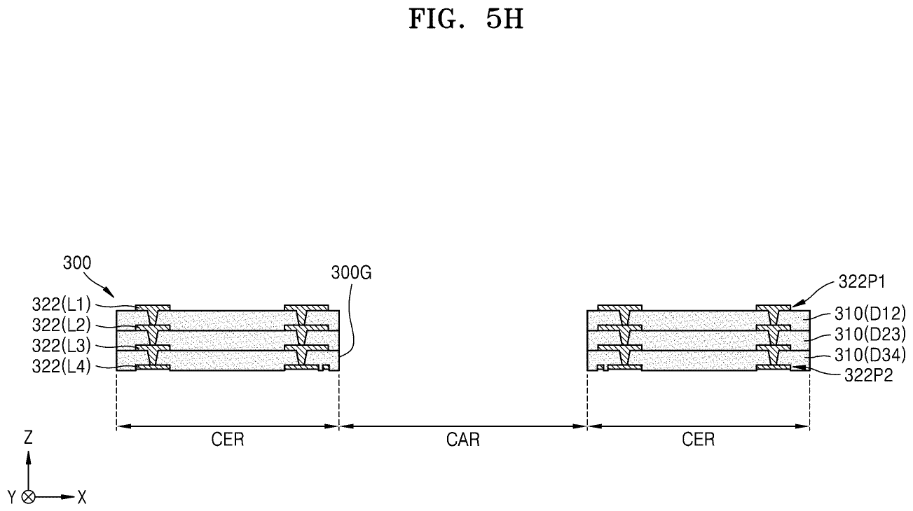

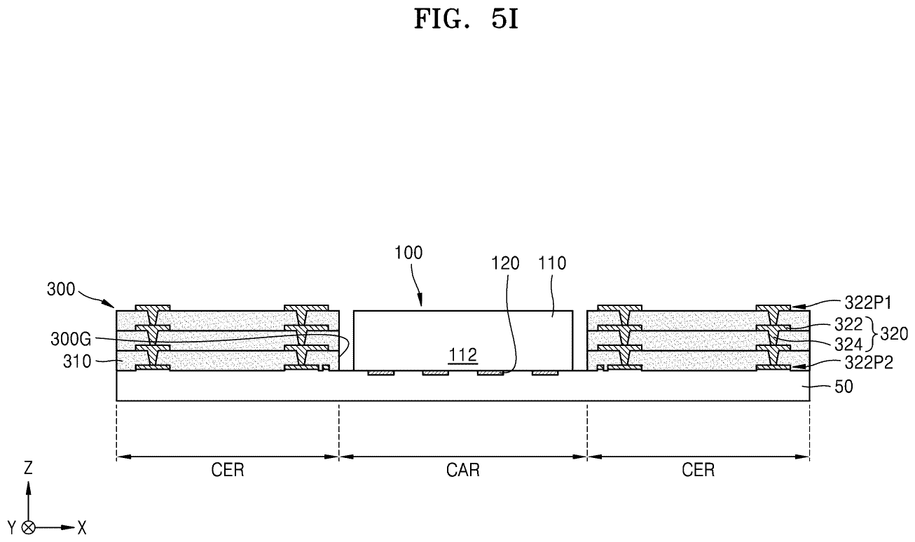

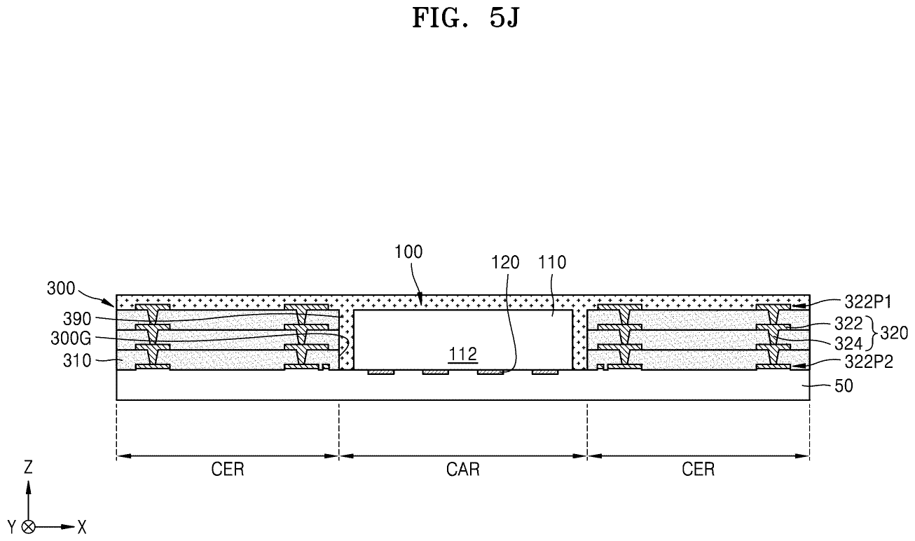

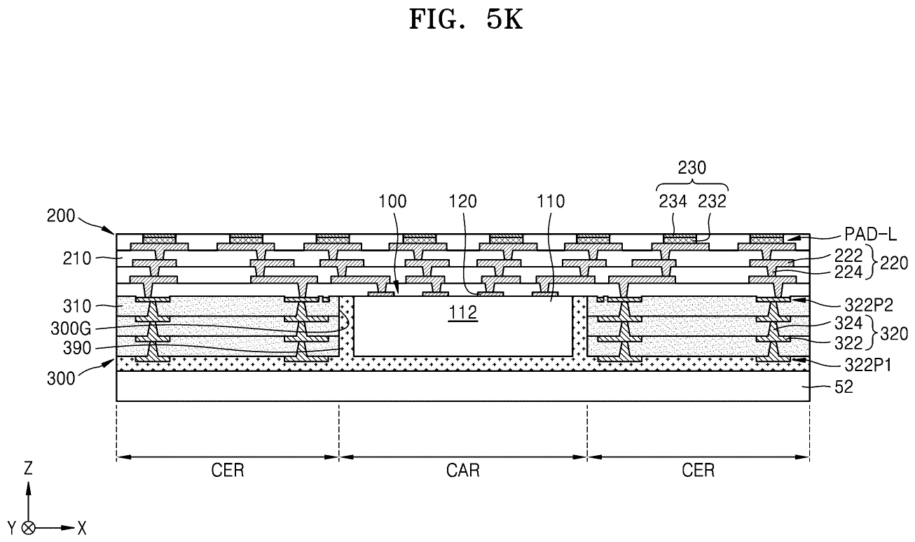

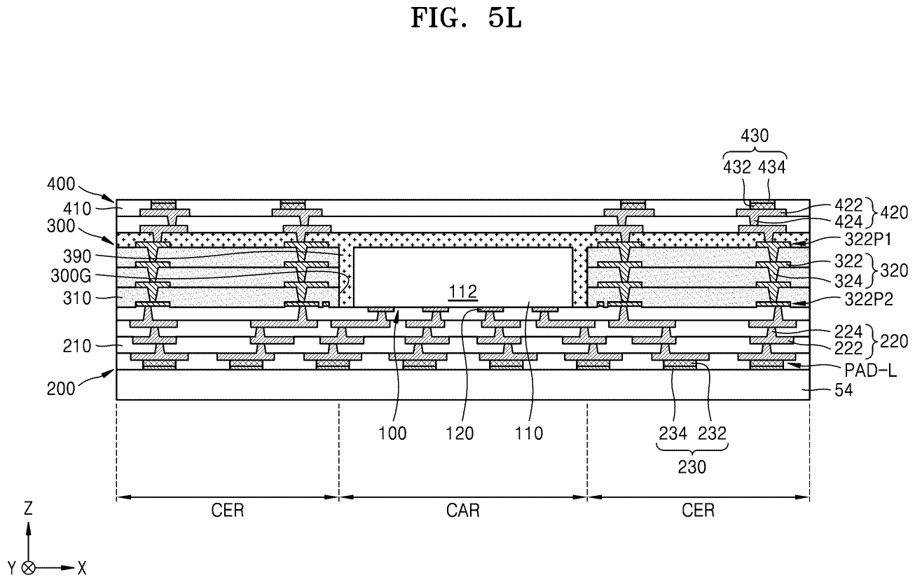

FIGS. 5A to 5D are cross-sectional views describing a method of manufacturing a semiconductor package, which is an FOPLP, according to embodiments.

Referring to FIG. 5A, a first support substrate 10 having a seed layer 20 formed on each of the upper and lower surfaces thereof is prepared. The first support substrate 10 may have a chip accommodation region CAR and a chip peripheral region CER around the chip accommodation region CAR. In some embodiments, the first support substrate 10 may include a prepreg layer or core layer including phenol resin, epoxy resin, and polyimide, a semiconductor substrate, a glass substrate, a ceramic substrate, and/or a plastic substrate. The seed layer 20 may include ED copper foil, RA copper foil, stainless steel foil, aluminum foil, ultra-thin copper foil, sputtered copper, copper alloys, or the like.

Referring to FIG. 5B, via connection patterns 322 are formed on the seed layer 20. The via connection patterns 322 may include the via connection patterns 322 constituting the fourth wiring layer LA shown in FIGS. 1A and 1B. In some embodiments, the via connection patterns 322 may be formed by a plating process, such as electroplating or electroless plating, using the seed layer 20 as a seed. In some embodiments, a mask pattern is formed on the seed layer 20, and a plating process is performed using the seed layer 20 as a seed to form a metal layer. Subsequently, the mask pattern and a portion of the metal layer located on the mask pattern are removed by performing a lift-off process, and accordingly, the via connection patterns 322 may be formed. The via connection patterns 322, adjacent to the chip accommodation region CAR among the via connection patterns 322, may have pad trenches 322T.

Referring to FIG. 5C, an extension base layer 310 is formed on the seed layer 20 and the via connection patterns 322 constituting the fourth wiring layer L4. Subsequently, a portion of the extension base layer 310 is removed to form through-holes that expose portions of the via connection patterns 322 constituting the fourth wiring layer L4. The extension base layer 310 may include a base dam 310D that fills the pad trench 322T of the via connection pattern 322, adjacent to the chip accommodation region CAR, among the via connection patterns 322 constituting the fourth wiring layer L4. Subsequently, extension vias 324 and via connection patterns 322 are formed. The extension vias 324 fill the through-holes, and the via connection patterns 322 are connected to the extension vias 324 and disposed on the extension base layer 310 to form the third wiring layer L3 shown in FIGS. 1A and 1B. The extension base layer 310 may function as an insulating layer D34 which is located between the via connection patterns 322 constituting the third wiring layer L3 and the via connection patterns 322 constituting the fourth wiring layer L4. The extension vias 324 may function as connection vias V23 which electrically connect the via connection patterns 322 constituting the third wiring layer L3 to the via connection patterns 322 constituting the fourth wiring layer L4.

In some embodiments, the extension base layer 310 is formed on the seed layer 20 and the via connection patterns 322 constituting the fourth wiring layer LA. Subsequently, a seed layer similar to the seed layer 20 may be formed on the extension base layer 310, and through-holes passing through the seed layer and the extension base layer 310 may be formed.

Referring to FIG. 5D, similar to that described in FIG. 5C, via connection patterns 322 are formed, which constitute the second wiring layer L2. Also, extension vias 324 are formed, which function as connection vias V23 for electrically connecting the via connection patterns 322 constituting the second wiring layer L2 to the via connection patterns 322 constituting the third wiring layer L3. Also, an extension base layer 310 is formed, which functions as an insulating layer D23 located between the via connection patterns 322 constituting the second wiring layer L2 and the via connection patterns 322 constituting the third wiring layer L3.

Referring to FIG. 5E, similar to that described in FIGS. 5C and 5D, via connection patterns 322 are formed, which constitute the first wiring layer L1. Also, extension vias 324 are formed, which function as connection vias V12 for electrically connecting the via connection patterns 322 constituting the first wiring layer L1 to the via connection patterns 322 constituting the second wiring layer L2. Also, an extension base layer 310 is formed, which functions as an insulating layer D12 located between the via connection patterns 322 constituting the first wiring layer L1 and the via connection patterns 322 constituting the second wiring layer L2. Accordingly, extension structures 300 are respectively formed on the upper surface and the lower surfaces of the first support substrate 10.

Referring to FIG. 5F, the extension structures 300 are respectively separated from the upper surface and the lower surfaces of the first support substrate 10. When the extension structures 300 are separated from the upper surface and the lower surfaces of the first support substrate 10, the seed layer 20 may be separated from the first support substrate 10 while attached to the extension structure 300.

Referring to FIGS. 5F and 5G together, the seed layer 20 is removed from the extension structure 300. During the process of removing the seed layer 20, a portion of the via connection patterns 322 constituting the fourth wiring layer L4, for example, a lower portion thereof, is removed, and accordingly, a plurality of lower recesses 322R may be formed.

Referring to FIGS. 5G and 5H together, a mounting space 300G is formed, which passes through the extension structure 300. The mounting space 300G may be formed by removing a portion of the extension structure 300, which is located in the chip accommodation region CAR, for example, a portion of the plurality of extension base layers 310.

Each of the via connection patterns 322 constituting the first wiring layer L1 may include the upper extension connection pad 322P1 and each of the via connection patterns 322 constituting the fourth wiring layer L4 may include the lower extension connection pad 322P2.

Referring to FIG. 5i, the extension structure 300 is attached to a second support substrate 50, and then, the semiconductor chip 100 to be accommodated in the mounting space 300G is attached to the second support substrate 50. The semiconductor chip 100 may be attached to the second support substrate 50 such that the plurality of chip pads 120 face the second support substrate 50. The second support substrate 50 may include a semiconductor substrate, a glass substrate, a ceramic substrate, or a plastic substrate. In some embodiments, the second support substrate 50 may include an adhesive layer on the upper side thereof. The semiconductor chip 100 may be attached to the second support substrate 50 such that the plurality of chip pads 120 are buried in the adhesive layer. In some embodiments, the extension structure 300 may be attached to the second support substrate 50 such that the adhesive layer fills the plurality of lower recesses 322R shown in FIG. 5G.

Referring to FIG. 5J, a filling insulating layer 390 is formed which fills the mounting space 300G and covers the upper surface of the extension structure 300 and the upper surface of the semiconductor chip 100. The filling insulating layer 390 may fill a space between the extension base layer 310 and the semiconductor chip 100 located in the mounting space 300G.

Referring to FIGS. 5J and 5K, the extension structure 300, the semiconductor chip 100, and the filling insulating layer 390 are separated from the second support substrate 50. Subsequently, the resulting object including the extension structure 300, the semiconductor chip 100, and the filling insulating layer 390 is turned upside down and attached to a third support substrate 52. The filling insulating layer 390 may be in contact with the third support substrate 52.

Subsequently, a first wiring structure 200 including a first redistribution insulating layer 210 and a plurality of first redistribution patterns 220 is formed on the extension structure 300, the semiconductor chip 100, and the filling insulating layer 390. The first wiring structure 200 may be formed on the extension structure 300, the semiconductor chip 100, and the filling insulating layer 390 such that the plurality of first redistribution patterns 220 are electrically connected to the plurality of chip pads 120 and the plurality of via structures 320.

Referring to FIGS. 5K and 5L together, the third support substrate 52 is separated from the filling insulating layer 390. Subsequently, the resulting object including the extension structure 300, the semiconductor chip 100, the filling insulating layer 390, and the first wiring structure 200 is turned upside down and attached to a fourth support substrate 54. The first wiring structure 200 may be in contact with the fourth support substrate 54.

Subsequently, a second wiring structure 400 including a second redistribution insulating layer 410 and a plurality of second redistribution patterns 420 is formed on the filling insulating layer 390. The lowermost ones of the plurality of second redistribution vias 424 of the plurality of second redistribution patterns 420 may pass through the filling insulating layer 390 and be connected to the upper surfaces of the via structures 320.

Subsequently, the fourth support substrate 54 is separated from the first wiring structure 200, and a plurality of external connection terminals 500 are attached to the lower surface of the first wiring structure 200 as shown in FIG. 1A. Accordingly, the semiconductor package 1 may be formed.

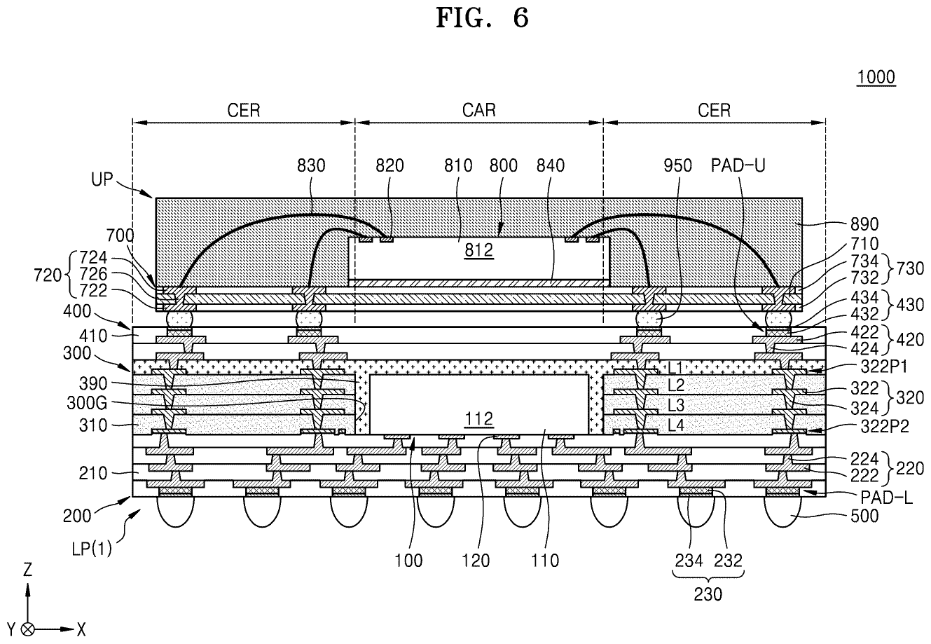

FIG. 6 is a cross-sectional view of a semiconductor package 1000, which is a package-on-package, according to embodiments.

Referring to FIG. 6, the semiconductor package 1000 may include a package-on-package in which an upper package UP is attached to a lower package LP. The lower package LP may include the semiconductor package 1 shown in FIG. 1A.

The lower package LP may include a first wiring structure 200, an extension structure 300 having a mounting space 300G on the first wiring structure 200, at least one semiconductor chip 100 accommodated in the mounting space 300G, a filling insulating layer 390 that fills the mounting space 300G and covers at least one semiconductor chip 100 and the extension structure 300, and a second wiring structure 400 on the filling insulating layer 390.

The upper package UP may be attached to the second wiring structure 400. The upper package UP may be electrically connected to a plurality of second redistribution patterns 420 of the second wiring structure 400. For example, the upper package UP may be connected to a plurality of upper connection pads PAD-U. For example, a plurality of package connection terminals 950 may be arranged between the upper package UP and the plurality of upper connection pads PAD-U. For example, the plurality of package connection terminals 950 may be attached to a plurality of upper connection pad layer 430. The plurality of package connection terminals 950 may electrically connect the lower package LP and the upper package UP to each other. In some embodiments, each of the plurality of package connection terminals 950 may include a bump, a solder ball, or the like.

The upper package UP includes a package substrate 700 and an auxiliary semiconductor chip 800 mounted on the package substrate 700. The auxiliary semiconductor chip 800 may include an auxiliary semiconductor substrate 810 having an active surface and an inactive surface opposite to each other, an auxiliary semiconductor device 812 formed on the active surface of the auxiliary semiconductor substrate 810, and a plurality of auxiliary chip pads 820 disposed on a third surface of the auxiliary semiconductor chip 800. The third surface of the auxiliary semiconductor chip 800 and the fourth surface of the auxiliary semiconductor chip 800 are opposite to each other, and the fourth surface of the auxiliary semiconductor chip 800 refers to the inactive surface of the auxiliary semiconductor substrate 810. The active surface of the auxiliary semiconductor substrate 810 is close to the third surface of the auxiliary semiconductor chip 800, and thus, the active surface of the auxiliary semiconductor substrate 810 and the third surface of the auxiliary semiconductor chip 800 are shown without distinction.

The auxiliary semiconductor chip 800 may include a memory semiconductor chip. For example, the auxiliary semiconductor chip 800 may include a DRAM chip, a SRAM chip, a flash memory chip, an electrically erasable and programmable read-only memory (EPROM) chip, a PRAM chip, a magnetic random access memory (MRAM) chip, or a RRAM chip. The auxiliary semiconductor substrate 810 and the auxiliary chip pad 820 are similar to the semiconductor substrate 110 and the chip pad 120, respectively, and thus, to the extent that an element is not described in detail with respect to this figure, it may be understood that the element is at least similar to a corresponding element that has been described elsewhere within the present disclosure. The semiconductor chip 100, the semiconductor substrate 110, the semiconductor device 112, and the chip pad 120 may be referred to as a first semiconductor chip, a first semiconductor substrate, a first semiconductor device, and a first chip pad or referred to as a lower semiconductor chip, a lower semiconductor substrate, a lower semiconductor device, and a lower chip pad. The auxiliary semiconductor chip 800, the auxiliary semiconductor substrate 810, the auxiliary semiconductor device 812, and the auxiliary chip pad 820 are referred to as a second semiconductor chip, a second semiconductor substrate, a second semiconductor device, and a second chip pad or referred to as an upper semiconductor chip, an upper semiconductor substrate, an upper semiconductor device, and an upper chip pad.

In some embodiments, the auxiliary semiconductor chip 800 may be electrically connected to the package substrate 700 through a plurality of bonding wires 830 connected to the plurality of auxiliary chip pads 820 and may be mounted on the package substrate 700 using a die attach film (DAF) 840. In some embodiments, the upper package UP may include a plurality of auxiliary semiconductor chips 800 spaced apart from each other in the horizontal direction and may also include a plurality of auxiliary semiconductor chips 800 stacked in the vertical direction. Also, the upper package UP may include a plurality of auxiliary semiconductor chips 800 that are electrically connected through a through-electrode and stacked in the vertical direction. Also, the auxiliary semiconductor chip 800 may be mounted on the package substrate 700 using a flip-chip method.

The package substrate 700 may include a PCB. For example, the package substrate 700 may include a double-sided PCB or a multi-layer PCB. The package substrate 700 may include at least one base insulating layer 710 and a plurality of wiring patterns 720. The plurality of wiring patterns 720 may include a plurality of lower conductive patterns 722, a plurality of upper conductive patterns 724, and a plurality of via patterns 726. The plurality of lower conductive patterns 722 may be disposed on the lower surface of the base insulating layer 710, the plurality of upper conductive patterns 724 may be disposed on the upper surface of the base insulating layer 710, and the plurality of via patterns 726 may pass through the base insulating layer 710 to connect the plurality of lower conductive patterns 722 and the plurality of upper conductive patterns 724 to each other. The base insulating layer 710 and the wiring patterns 720 are substantially similar to the extension base layer 310 and the via structures 320, respectively, and thus, to the extent that an element is not described in detail with respect to this figure, it may be understood that the element is at least similar to a corresponding element that has been described elsewhere within the present disclosure. FIG. 6 illustrates that the package substrate 700 includes a single layer of the base insulating layer 710. However, this is an example, and the embodiment is not necessarily limited thereto. For example, the package substrate 700 may include two or more base insulating layers 710 stacked on each other and may further include conductive patterns between the two or more base insulating layers 710.

In some embodiments, the package substrate 700 may include a solder resist layer 730 disposed on the upper surface and the lower surfaces of the base insulating layer 710. The solder resist layer 730 may include a lower solder resist layer 732 disposed on the lower surface of the base insulating layer 710 and an upper solder resist layer 734 disposed on the upper surface of the base insulating layer 710. The plurality of lower conductive patterns 722 among the plurality of wiring patterns 720 may be exposed to the lower surface of the package substrate 700 without being covered by the lower solder resist layer 732, and the plurality of upper conductive patterns 724 among the plurality of wiring patterns 720 may be exposed to the upper surface of the package substrate 700 without being covered by the upper solder resist layer 734.

The plurality of package connection terminals 950 may be respectively attached to the plurality of lower conductive patterns 722 and the plurality of bonding wires 830 may be respectively connected to the plurality of upper conductive patterns 724.

In some embodiments, the upper package UP may further include a package molding layer 890 that at least partially surrounds the auxiliary semiconductor chip 800 and the plurality of bonding wires 830 on the package substrate 700. For example, the package molding layer 890 may include a molding member including an EMC.

While the inventive concept has been particularly shown and described with reference to embodiments thereof, it will be understood that various changes in form and details may be made therein without departing from the spirit and scope of the present disclosure.

What is claimed is:

1. A semiconductor package, comprising:
a first wiring structure;
an extension structure disposed on the first wiring structure, the extension structure comprising an extension base layer and a plurality of via structures, and having a mounting space passing through the extension base layer, wherein the plurality of via structures comprises a plurality of via connection patterns disposed on upper and lower surfaces of the extension base layer and a plurality of extension vias connecting two via connection patterns, among the plurality of via connection patterns, to each other, the two via connection patterns being at different vertical levels from one another;
a semiconductor chip disposed in the mounting space and electrically connected to the first wiring structure;
a filling insulating layer filling the mounting space; and
a second wiring structure disposed on the extension structure and the filling insulating layer and electrically connected to the first wiring structure through the plurality of via structures,
wherein lowermost via connection patterns, among the plurality of via connection patterns, comprise a plurality of first lower connection pads, and
wherein the extension base layer comprises base dams respectively passing through the plurality of first lower connection pads and protruding and extending from the plurality of first lower connection pads.

2. The semiconductor package of claim 1, wherein the plurality of first lower connection pads are arranged around the mounting space.

3. The semiconductor package of claim 2, wherein a lower surface of each of the lowermost via connection patterns, among the plurality of via connection patterns, is at a higher vertical level than a lower surface of the extension base layer, and
wherein the extension base layer and the lower surfaces of the lowermost via connection patterns, among the plurality of via connection patterns, define a plurality of lower recesses.

4. The semiconductor package of claim 3, wherein the filling insulating layer includes a bleeding portion extending from the mounting space into some of the plurality of lower recesses.

5. The semiconductor package of claim 4, wherein the lowermost via connection patterns, among the plurality of via connection patterns, further comprise a plurality of second lower connection pads that at least partially surround the plurality of first lower connection pads, and
wherein the bleeding portion of the filling insulating layer extends into lower recesses, among the plurality of lower recesses, defined by the extension base layer and lower surfaces of the plurality of first lower connection pads, but does not extend into lower recesses, among the plurality of lower recesses, defined by the extension base layer and lower surfaces of the plurality of second lower connection pads.

6. The semiconductor package of claim 1, wherein the base dam is disposed between the mounting space and an extension via connected to each of the plurality of first lower connection pads, among the plurality of extension vias.

7. The semiconductor package of claim 6, wherein the base dam at least partially surrounds a region of the extension via that is connected to each of the plurality of first lower connection pads facing the mounting space.

8. The semiconductor package of claim 6, wherein the base dam comprises a first base dam and a second base dam which are spaced apart from each other between the mounting space and the extension via connected to each of the plurality of first lower connection pads.

9. The semiconductor package of claim 1, wherein a thickness of the lowermost via connection pattern, among the plurality of via connection patterns, is less than thicknesses of each of the other via connection patterns, among the plurality of via connection patterns.

10. The semiconductor package of claim 1, wherein the lowermost via connection patterns, among the plurality of via connection patterns, are buried in the extension base layer, and uppermost via connection patterns, among the plurality of via connection patterns, protrude upward from the upper surface of the extension base layer.

11. A semiconductor package, comprising:
a first wiring structure;
a second wiring structure disposed above the first wiring structure;
an extension structure disposed between the first wiring structure and the second wiring structure and having a mounting space passing through the extension structure from an upper surface to a lower surface thereof;
a semiconductor chip disposed inside the mounting space; and
a filling insulating layer filling the mounting space and covering the upper surface of the semiconductor chip and an upper surface of the extension structure,
wherein the extension structure comprises a plurality of extension base layers stacked on each other, a plurality of via connection patterns disposed on the upper and lower surfaces of each of the plurality of extension base layers, and a plurality of extension vias passing through at least one extension base layer, among the plurality of extension base layers, and connecting two via connection patterns, among the plurality of via connection patterns, to each other which are at different vertical levels from one another,
wherein lowermost via connection patterns, among the plurality of via connection patterns, comprise a plurality of first lower connection pads arranged around the mounting space and each having a pad trench, and a plurality of second lower connection pads at least partially surrounding the plurality of first lower connection pads, and
wherein the extension base layer comprises a base dam which passes through each of the plurality of first lower connection pads while filling the pad trench, and protrudes downward from a lower surface of each of the plurality of first lower connection pads.

12. The semiconductor package of claim 11, wherein each of the plurality of first lower connection pads has a shape in which a first portion having a semicircular shape and a second portion having a rectangular shape are coupled to each other, and
wherein the pad trench is disposed in the second portion of each of the plurality of first lower connection pads.

13. The semiconductor package of claim 12, wherein each of the pad trench and the base dam has an arc shape.

14. The semiconductor package of claim 13, wherein a radius of the arc shape of each of the pad trench and the base dam is greater than a radius of the semicircular shape of the first portion of each of the plurality of first lower connection pads.

15. The semiconductor package of claim 11, wherein the plurality of first lower connection pads and the plurality of second lower connection pads are buried in a lowermost extension base layer among the plurality of extension base layers and each have a lower surface at a vertical level that is higher than a bottom of the lowermost extension base layer.

16. The semiconductor package of claim 15, wherein via connection patterns, which are at vertical levels higher than the lowermost via connection patterns and lower than uppermost via connection patterns among the plurality of via connection patterns, have lower surfaces at the same vertical level and are buried in any one of the plurality of extension base layers.

17. The semiconductor package of claim 11, wherein the filling insulating layer comprises a bleeding portion that extends from the mounting space along the lower surface of the extension structure and contacts the lower surface of at least one of the plurality of first lower connection pads.

18. A semiconductor package, comprising:
a first wiring structure comprising a first redistribution insulating layer, a plurality of first redistribution line patterns disposed on at least one of upper and lower surfaces of the first redistribution insulating layer, and a plurality of first redistribution vias passing through the first redistribution insulating layer and respectively connected to some of the plurality of first redistribution line patterns;
an extension structure disposed on the first wiring structure, the extension structure comprising a plurality of extension base layers and a plurality of via structures passing through the plurality of extension base layers and connected to some of the plurality of first redistribution vias, and having a mounting space passing through the plurality of extension base layers;
a semiconductor chip disposed in the mounting space and comprising a plurality of chip pads connected to the others of the plurality of first redistribution vias;
a filling insulating layer filling the mounting space and covering an upper surface of the semiconductor chip and an upper surface of the extension structure; and
a second wiring structure disposed on the filling insulating layer and comprising a second redistribution insulating layer, a plurality of second redistribution line patterns disposed on at least one of the upper and lower surfaces of the second redistribution insulating layer, and a plurality of second redistribution vias passing through the second redistribution insulating layer and respectively connected to some of the plurality of second redistribution line patterns, the second wiring structure being electrically connected to the first wiring structure through the plurality of via structures,
wherein the plurality of via structures comprises a plurality of via connection patterns disposed on upper and lower surfaces of each of the plurality of extension base layers and a plurality of extension vias passing through at least one extension base layer and connecting two via connection patterns, among the plurality of via connection patterns, to each other, the two via connection patterns being at different vertical levels from one another,
wherein lowermost via connection patterns, among the plurality of via connection patterns, are buried in a lowermost extension base layer, among the plurality of extension base layers, and comprise a plurality of first lower connection pads arranged around the mounting space and each having a pad trench and a plurality of second lower connection pads at least partially surrounding the plurality of first lower connection pads, and
wherein the extension base layer comprises a base dam which passes through each of the plurality of first lower connection pads while filling the pad trench and extends into the first redistribution insulating layer.

19. The semiconductor package of claim 18, wherein each of the plurality of first lower connection pads and the plurality of second lower connection pads has a lower surface at a vertical level that is higher than a bottom of the lowermost extension base layer by about 2 μm to about 5 μm.

20. The semiconductor package of claim 18, wherein the base dam is disposed between the mounting space and an extension via connected to each of the plurality of first lower connection pads, among the plurality of extension vias, and extends with a horizontal width of about 10 μm to about 30 μm to at least partially surround a region of the extension via facing the mounting space.
